(19) United States
(12) Patent Application Publication
(10) Pub. No.: US 2026/0198365 A1
(43) Pub. Date: Jul. 9, 2026

(54) SEMICONDUCTOR PACKAGE MANUFACTURING METHOD

(71) Applicant: SONY SEMICONDUCTOR SOLUTIONS CORPORATION, Kanagawa (JP)

(72) Inventors: Kei FUKUHARA, Kanagawa (JP); Yuki SUDA, Kanagawa (JP); Susumu FUJIWARA, Kanagawa (JP)

(73) Assignee: SONY SEMICONDUCTOR SOLUTIONS CORPORATION, Kanagawa (JP)

(21) Appl. No.: 19/133,062

(22) PCT Filed: Oct. 12, 2023
(86) PCT No.: PCT/JP2023/036980

§ 371 Date: May 27, 2025

(30) Foreign Application Priority Data
Dec. 7, 2022 (JP) 2022-195298

(51) Int. Cl. H10W 74/01; H10W 74/10; H10W 74/15; H10W 90/00

(52) U.S. Cl. CPC H10W 74/012; H10W 74/014; H10W 74/121; H10W 74/15; H10W 90/722

(57) ABSTRACT

To suppress warpage of a wafer in a semiconductor package manufacturing process using an underfill. In a filling procedure, a portion along an outer periphery of each of a plurality of integrated circuits bonded to the wafer is filled with a photosensitive resin as a first underfill. In an exposure procedure, the first underfill is cured by exposure. In a sealing procedure, the plurality of integrated circuits and the first underfill are sealed by a sealing material. In a dicing procedure, the wafer is divided into a predetermined number of semiconductor chips.

### TECHNICAL FIELD

The present technology relates to a semiconductor package manufacturing method. Specifically, the present technology relates to a semiconductor package manufacturing method including a wafer level process.

### BACKGROUND ART

In related art, in a manufacturing process before dicing, an underfill is used to suppress warpage of a wafer. For example, a manufacturing method has been proposed in which a dam is formed between chips after die bonding, an outer peripheral portion of a wafer is filled with an underfill, and then the dam is removed (see, for example, Patent Document 1).

### CITATION LIST

### Patent Document

Patent Document 1: U.S. Pat. No. 10,504,824

### SUMMARY OF THE INVENTION

### Problems to be Solved by the Invention

In the above-described technology in the related art, by the outer peripheral portion of the wafer being filled with the underfill, warpage of the wafer due to subsequent heat treatment is suppressed. However, in a case where stress greater than expected is generated in the wafer, the wafer may be warped.

The present technology has been made in view of such circumstances, and an object of the present technology is to suppress warpage of a wafer in a semiconductor package manufacturing process using an underfill.

### Solutions to Problems

The present technology has been made to solve the above-described problem, and a first aspect thereof is a semiconductor package manufacturing method including: a filling procedure of filling a portion along an outer periphery of each of a plurality of integrated circuits bonded to a wafer with a photosensitive resin as a first underfill; an exposure procedure of curing the first underfill by exposure; a sealing procedure of sealing the plurality of integrated circuits and the first underfill by a sealing material; and a dicing procedure of dividing the wafer into a predetermined number of semiconductor chips. This brings about an effect of suppressing warpage of the wafer.

Furthermore, in the first aspect, the semiconductor package manufacturing method may further include a patterning procedure of forming a grid-like dam on the wafer before the filling procedure. This brings about an effect of separating each of the integrated circuits.

Furthermore, in the first aspect, laser processing and surface modification may be performed in the patterning procedure. This brings about an effect of suppressing warpage.

Furthermore, in the first aspect, the patterning procedure may include a procedure of forming a resist with a predetermined gap left between the plurality of integrated circuits, and a procedure of forming the dam by plasma processing. This brings about an effect of suppressing warpage.

Furthermore, in the first aspect, the patterning procedure may include: a procedure of forming a resist on the entire surface of the wafer; and a procedure of removing the resist while leaving a grid-like portion by lithography. This brings about an effect of suppressing warpage.

Furthermore, in the first aspect, a ratio of a thickness of the sealing material to a thickness of the integrated circuits may be not less than 0.5. This brings about an effect of suppressing warpage.

Furthermore, in the first aspect, in the filling procedure, filling with the first underfill may be performed so that the first underfill has a fillet shape when viewed from a direction parallel to a substrate plane of the wafer. This brings about an effect of improving a warpage suppressing effect.

Furthermore, in the first aspect, the plurality of integrated circuits may include outer integrated circuits adjacent to an outer periphery of the wafer and inner integrated circuits that do not correspond to the outer integrated circuits, and in the filling procedure, a portion along an inner side of the outer integrated circuits and outer peripheries of the inner integrated circuits may be filled with the first underfill. This brings about an effect of improving a warpage suppressing effect.

Furthermore, in the first aspect, in the filling procedure, a portion along part of the outer periphery of each of the plurality of integrated circuits may be filled with the first underfill. This brings about an effect of improving a warpage suppressing effect.

Furthermore, in the first aspect, a contact angle of a portion where the first underfill is in contact with the wafer may be any of 30°, 45°, and 60°. This brings about an effect of improving a warpage suppressing effect.

Furthermore, in the first aspect, part of the first underfill may be in contact with side walls of the integrated circuits. This brings about an effect of improving a warpage suppressing effect.

Furthermore, in the first aspect, the semiconductor package manufacturing method may further include a patterning procedure of forming a grid-like dam on the wafer before the filling procedure, each of the integrated circuits may have a rectangular shape when viewed from a direction perpendicular to the substrate, a region surrounded by the dam when viewed from the direction perpendicular to the substrate may have a rectangular shape, and a distance from one side of four sides of each of the integrated circuits to an inner wall of the dam when viewed from the direction perpendicular to the substrate may be longer than a distance from the remaining three sides to the inner wall of the dam. This brings about an effect of facilitating filling with the underfill.

Furthermore, in the first aspect, the semiconductor package manufacturing method may further include a patterning procedure of forming a grid-like dam in the wafer before the filling procedure, and a U-shaped recess protruding outward may be formed in a region surrounded by the dam when viewed from a direction perpendicular to the substrate. This brings about an effect of facilitating filling with the underfill.

Furthermore, in the first aspect, the semiconductor package manufacturing method may further include a patterning procedure of forming a grid-like dam on the wafer before the filling procedure, and part of the dam may have a step. This brings about an effect of promoting filling with the underfill.

Furthermore, in the first aspect, the semiconductor package manufacturing method may further include a patterning procedure of forming a grid-like dam on the wafer before the filling procedure, and part of the dam may have a slope. This brings about an effect of promoting filling with the underfill.

Furthermore, in the first aspect, the semiconductor package manufacturing method may further include a patterning procedure of forming a grid-like dam on the wafer before the filling procedure, and a predetermined number of slits may be formed in part of the dam. This brings about an effect of promoting filling with the underfill.

Further, in the first aspect, a predetermined number of trenches may be formed in the wafer. This brings about an effect of promoting filling with the underfill.

Furthermore, in the first aspect, the semiconductor package manufacturing method may further include a procedure of mounting the semiconductor chip on a substrate, a procedure of arranging a passive component around the semiconductor chip, a procedure of sealing the passive component by a mold resin, and a procedure of performing filling with a second underfill. This brings about an effect of reducing man-hours.

Furthermore, in the first aspect, the semiconductor package manufacturing method may further include a procedure of mounting the semiconductor chip in a cavity provided in a substrate, a procedure of filling the cavity with a second underfill, and a procedure of arranging a passive component around the cavity. This brings about an effect of reducing man-hours.

Furthermore, in the first aspect, the semiconductor package manufacturing method may further include a procedure of mounting the semiconductor chip on a substrate, a procedure of arranging a passive component around the semiconductor chip, a procedure of sealing the passive component by a substrate material, a procedure of performing filling with a second underfill, and a procedure of arranging a surface mount technology component on the substrate material. This brings about an effect of reducing a footprint.

### BRIEF DESCRIPTION OF DRAWINGS

FIG. 1 is a view for explaining a die bonding process in a first embodiment of the present technology.

FIG. 2 is a view for explaining a patterning process in the first embodiment of the present technology.

FIG. 3 is a view for explaining an underfill filling process in the first embodiment of the present technology.

FIG. 4 is a view for explaining an underfill removal process in the first embodiment of the present technology.

FIG. 5 is a view for explaining a sealing process in the first embodiment of the present technology.

FIG. 6 is a flowchart indicating an example of a manufacturing method in the first embodiment of the present technology.

FIG. 7 is a view illustrating an example of a plan view and a cross-sectional view of a wafer at the time of forming an underfill in a comparative example.

FIG. 8 is a view for explaining a resist film forming process in a first modification of the first embodiment of the present technology.

FIG. 9 is a view for explaining processes until resist removal in the first modification of the first embodiment of the present technology.

FIG. 10 is a view for explaining a resist film forming process in a second modification of the first embodiment of the present technology.

FIG. 11 is a view for explaining a lithography process in the second modification of the first embodiment of the present technology.

FIG. 12 is a view comparing respective characteristics of the first embodiment of the present technology, each modification, and the comparative example.

FIG. 13 is a view for explaining an underfill filling process in a second embodiment of the present technology.

FIG. 14 is a view for explaining a sealing process in the second embodiment of the present technology.

FIG. 15 is a flowchart indicating an example of a manufacturing method in the second embodiment of the present technology.

FIG. 16 is a view comparing respective characteristics of the second embodiment of the present technology and each comparative example.

FIG. 17 is a view illustrating an example of a plan view and a cross-sectional view of a wafer at the time of forming an underfill in a third embodiment of the present technology.

FIG. 18 is a view illustrating an example of a cross-sectional view of a wafer at the time of forming an underfill in a first modification of the third embodiment of the present technology.

FIG. 19 is a view illustrating an example of a cross-sectional view of a wafer at the time of forming an underfill in a second modification of the third embodiment of the present technology.

FIG. 20 is a view illustrating an example of a plan view and a cross-sectional view of a wafer at the time of forming an underfill in a third modification of the third embodiment of the present technology.

FIG. 21 is a view illustrating an example of a cross-sectional view of a wafer at the time of forming an underfill in a fourth modification of the third embodiment of the present technology.

FIG. 22 is a view illustrating an example of a cross-sectional view of a wafer at the time of forming an underfill in a fifth modification of the third embodiment of the present technology.

FIG. 23 is a view comparing respective characteristics of the third embodiment of the present technology, each modification, and each comparative example.

FIG. 24 is a view illustrating an example of a plan view and a cross-sectional view of a wafer at the time of patterning in a fourth embodiment of the present technology.

FIG. 25 is a view illustrating an example of a plan view of a dam in a first modification of the fourth embodiment of the present technology.

FIG. 26 is a view illustrating an example of a wafer and a dam in a second modification of the fourth embodiment of the present technology.

FIG. 27 is a view illustrating an example of a wafer and a dam in a third modification of the fourth embodiment of the present technology.

FIG. 28 is a view illustrating an example of a top view and a cross-sectional view of a wafer at the time of filling with an underfill in a fourth modification of the fourth embodiment of the present technology.

FIG. 29 is a view illustrating another example of a trench and a dam in the fourth modification of the fourth embodiment of the present technology.

FIG. 30 is a view for explaining a die bonding process in a fifth embodiment of the present technology.

FIG. 31 is a view for explaining a component arrangement process in the fifth embodiment of the present technology.

FIG. 32 is a view for explaining a sealing process in the fifth embodiment of the present technology.

FIG. 33 is a view for explaining an underfill filling process in the fifth embodiment of the present technology.

FIG. 34 is a flowchart indicating an example of a manufacturing method in the fifth embodiment of the present technology.

FIG. 35 is a cross-sectional view illustrating an example of a semiconductor package in a comparative example.

FIG. 36 is a view for explaining a die bonding process in a first modification of the fifth embodiment of the present technology.

FIG. 37 is a view for explaining an underfill filling process in the first modification of the fifth embodiment of the present technology.

FIG. 38 is a view for explaining a component arrangement process in the first modification of the fifth embodiment of the present technology.

FIG. 39 is a view for explaining a die bonding process in a second modification of the fifth embodiment of the present technology.

FIG. 40 is a view for explaining a lower component arrangement process in the second modification of the fifth embodiment of the present technology.

FIG. 41 is a view for explaining a sealing process in the second modification of the fifth embodiment of the present technology.

FIG. 42 is a view for explaining an underfill filling process in the second modification of the fifth embodiment of the present technology.

FIG. 43 is a view for explaining an upper component arrangement process in the second modification of the fifth embodiment of the present technology.

FIG. 44 is a block diagram illustrating a schematic configuration example of a vehicle control system.

FIG. 45 is an explanatory diagram illustrating an example of an installation position of an imaging section.

### MODE FOR CARRYING OUT THE INVENTION

Modes for carrying out the present technology (hereinafter, referred to as embodiments) will be described below. The description will be given in the following order.
1. First Embodiment (Example of Filling with Underfill after Patterning)
2. Second Embodiment (Example of Filling with Underfill without Patterning)
3. Third Embodiment (Example of Filling with Underfill to Have Fillet Shape)
4. Fourth Embodiment (Example of Filling with Underfill After Patterning with Changed Shape)
5. Fifth Embodiment (Example of Filling with Underfill after Patterning and Mounting on Substrate after Dicing)
6. Example of Application to Mobile Body

### 1. First Embodiment

### [Semiconductor Package Manufacturing Method]

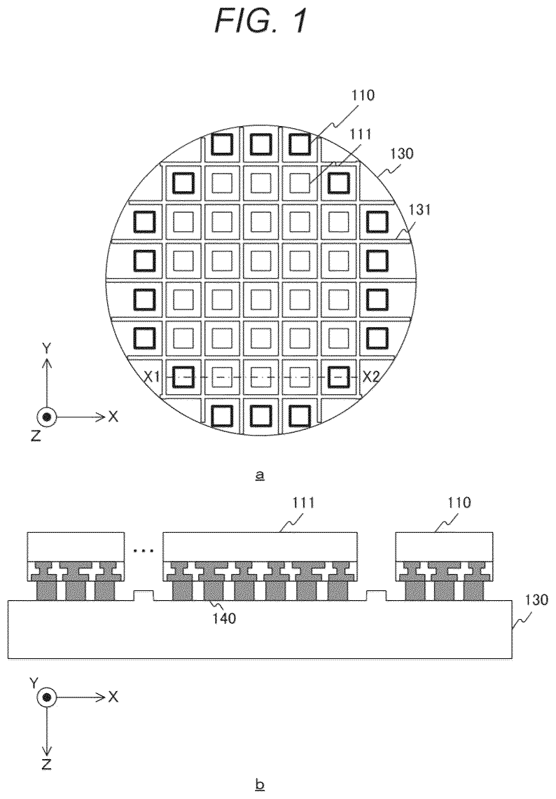

A semiconductor package manufacturing method in a first embodiment will be described with reference to FIG. 1 to FIG. 5.

First, as illustrated in FIG. 1, a plurality of integrated circuits is bonded (that is, die bonded) to a wafer 130. In the drawing, a is an example of a plan view of the wafer 130, and b in the drawing is an example of a cross-sectional view taken along a line segment X1-X2 in a of the drawing.

Thick-frame rectangles in a of the drawing indicate integrated circuits 110 adjacent to an outer periphery of the wafer 130. The other rectangles indicate integrated circuits 111 inside the integrated circuits 110. Further, a predetermined axis parallel to a substrate plane of the wafer 130 is set as an “X axis”, and an axis perpendicular to the substrate plane is set as a “Z axis”. An axis perpendicular to the X axis and the Z axis is set as a “Y axis”.

In the drawing, b is a cross-sectional view when viewed from a Y-axis direction. In b of the drawing, only right ends of the plurality of inner integrated circuits 111 are illustrated, and the rest is omitted. In addition, the integrated circuits 110 and 111 are bonded to the wafer 130 by a plurality of electrodes 140, and a wafer-circuit distance from the substrate plane of the wafer 130 to lower ends of the integrated circuits 110, or the like, is H0.

The wafer 130 has a grid shape when viewed from a Z-axis direction, and a portion protruding from the substrate plane when viewed from a X-axis direction or the Y-axis direction is formed by laser processing. Each of the integrated circuits 110 and 111 is arranged in each of the regions surrounded by the grid-like portion.

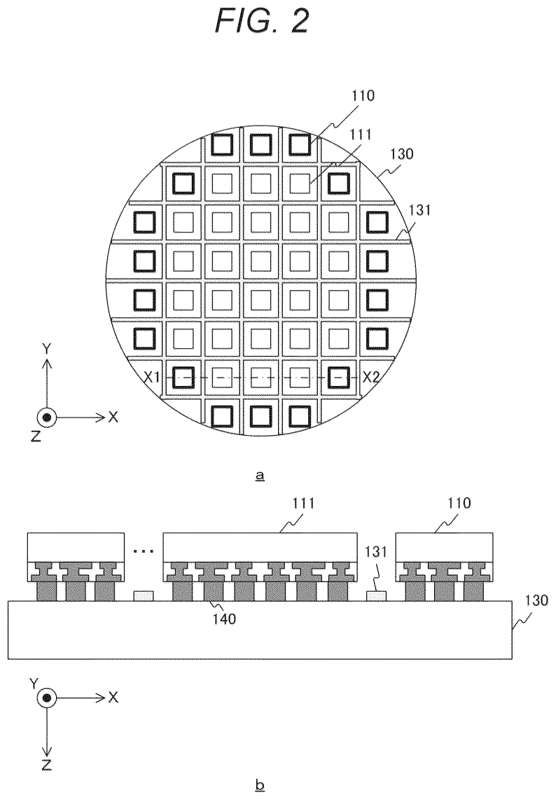

Next, as illustrated in FIG. 2, surface modification for imparting hydrophobicity to the grid-like portion is performed. The portion subjected to the surface modification is referred to as a dam 131. In the drawing, a is an example of a plan view of the wafer 130, and b in the drawing is an example of a cross-sectional view taken along the line segment X1-X2 in a of the drawing.

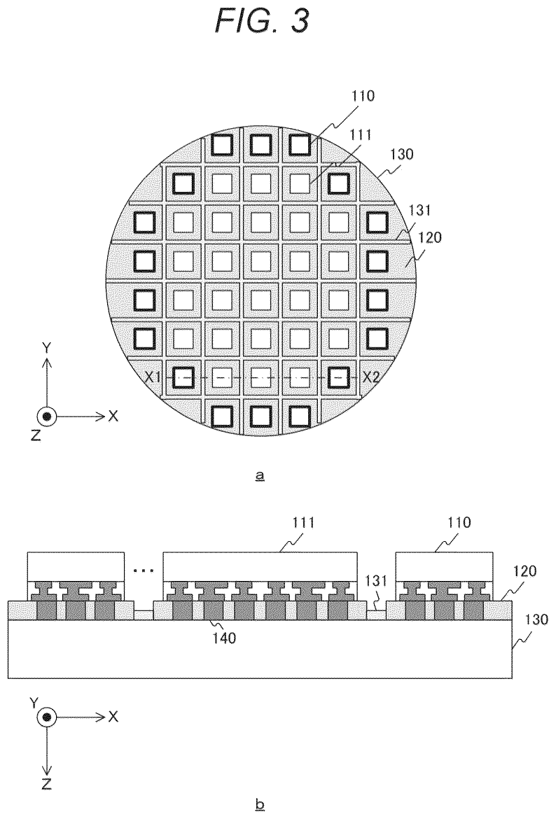

Subsequently, as illustrated in FIG. 3, a portion along an outer periphery of each of the integrated circuits 110 and 111 is filled with a photosensitive resin (such as an ultraviolet curable resin) as an underfill 120. In the drawing, a is an example of a plan view of the wafer 130, and b in the drawing is an example of a cross-sectional view taken along the line segment X1-X2 in a of the drawing.

For example, an acrylic resin, an epoxy resin, a silicone resin, an epoxy resin containing an inorganic filler, or the like, is used as the underfill 120. A region to be filled with the underfill 120 is separated for each integrated circuit by the grid-like dam 131, and thus, each region can be uniformly filled with the underfill 120.

Then, the underfill 120 is cured by exposure to ultraviolet rays, or the like.

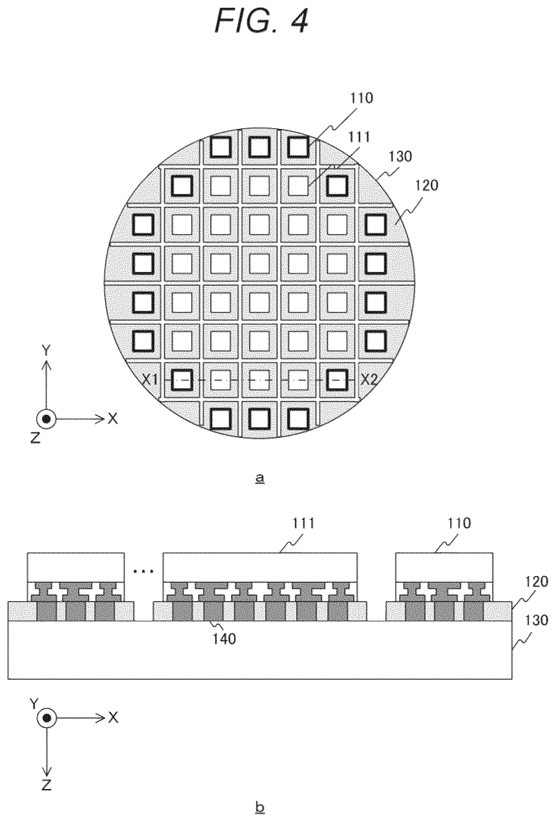

Next, as illustrated in FIG. 4, the dam 131 is removed by laser processing, or the like. Then, in various processes such as a process of forming a circuit or a solder ball on the wafer 130, heat treatment is performed on the wafer 130. In addition, the wafer 130 may be ground to be thin. The underfill 120 can sufficiently suppress warpage of the wafer 130 during heat treatment or grinding.

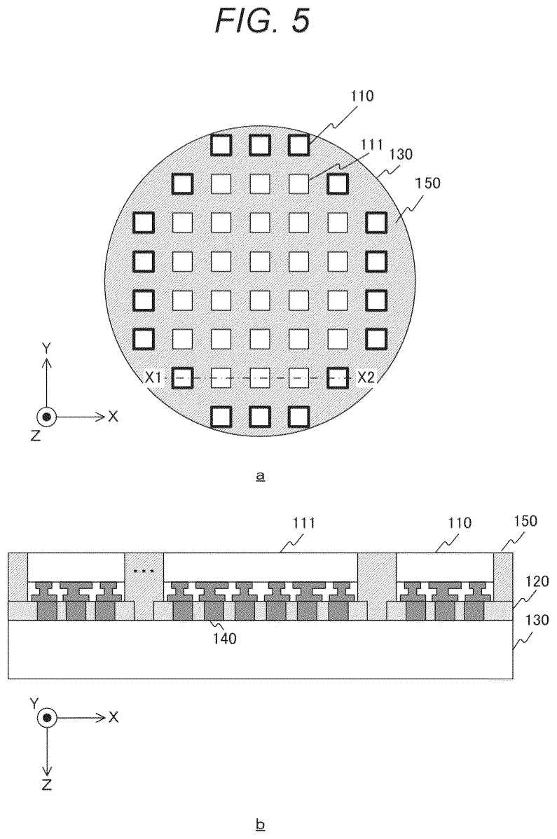

Subsequently, as illustrated in FIG. 5, a portion between the integrated circuits is sealed by a sealing material 150. In the drawing, a is an example of a plan view of the wafer 130, and b in the drawing is an example of a cross-sectional view taken along the line segment X1-X2 in a of the drawing. Note that although only a portion between the integrated circuits is filled with the sealing material 150, the entire surface of the wafer 130 including an upper portion of each integrated circuit can be covered with the sealing material 150 in addition to the portion between the integrated circuits.

Then, the wafer 130 is divided into a predetermined number of semiconductor chips by dicing. Each of the semiconductor chips is mounted on a substrate. Thus, a semiconductor package is manufactured.

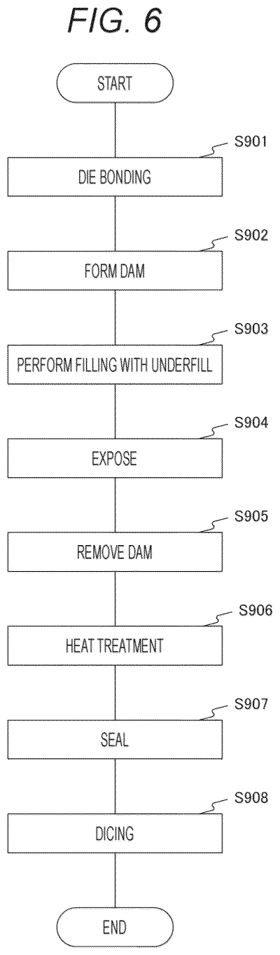

FIG. 6 is a flowchart indicating an example of a manufacturing method in the first embodiment of the present technology. A plurality of integrated circuits is bonded (that is, die bonded) to the wafer 130 (step S901). Next, the dam 131 is formed (step S902), and filling with the underfill 120 is performed (step S903). Then, the underfill 120 is cured by exposure (step S904). Subsequently, the dam 131 is removed (step S905), and various kinds of heat treatment are performed (step S906). Then, a portion between the integrated circuits is sealed by the sealing material 150 (step S907), and dicing is performed (step S908). After dicing, various processes such as a process of mounting on a substrate are performed to manufacture a semiconductor package.

Here, a manufacturing method in which the underfill 120 is formed only on an outer peripheral portion of the wafer 130 as described in Patent Document 1, is assumed as a comparative example.

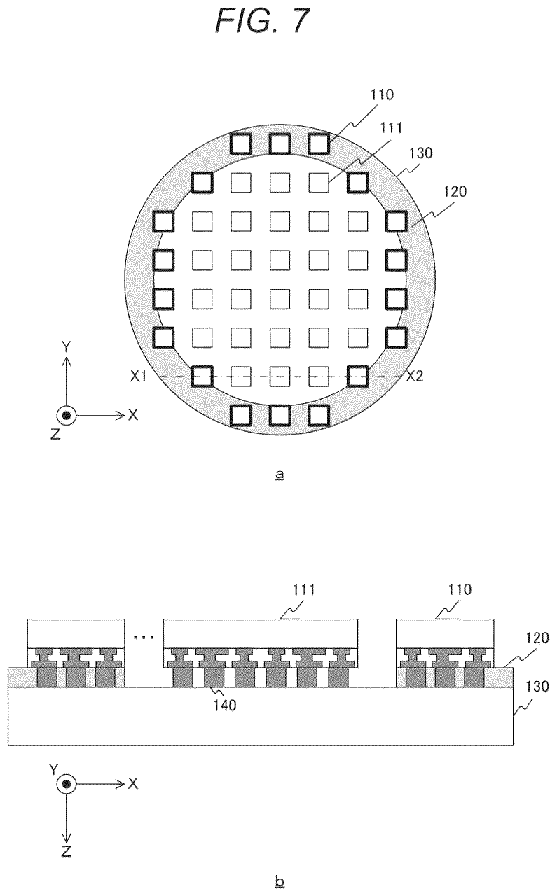

FIG. 7 is a view illustrating an example of a plan view and a cross-sectional view of the wafer 130 at the time of forming the underfill in the comparative example. In the drawing, a is an example of a plan view of the wafer 130, and b in the drawing is an example of a cross-sectional view taken along the line segment X1-X2 in a of the drawing.

In a case where the underfill 120 has a relatively high viscosity, the underfill 120 is less likely to penetrate into lower portions of the integrated circuits, and if the underfill 120 is applied to the entire surface, ununiformity may occur. In this case, as illustrated in the drawing, only the outer peripheral portion of the wafer 130, more specifically, a region along the outer periphery of each of the outer integrated circuits 110 and the lower portion thereof are filled with the underfill 120. On the other hand, the outer periphery and the lower portion of each of the inner integrated circuits 110 are not filled with the underfill 120.

In the comparative example, there is a possibility that the wafer 130 is warped in a case where stress greater than expected is applied at the time of heat treatment or grinding in the subsequent stage. This warpage may degrade a yield of the semiconductor package.

On the other hand, in the first embodiment, not only a portion on the outer periphery of each of the outer integrated circuits 110 but also a portion on the outer periphery of each of the inner integrated circuits 111 are filled with the underfill 120, and thus, warpage of the wafer 130 can be sufficiently suppressed. In addition, the respective integrated circuits are separated by the hydrophobic dam 131, and thus, filling can be uniformly performed with even the underfill 120 having a relatively low viscosity.

As described above, according to the first embodiment of the present technology, a portion along the outer periphery of each of the integrated circuits 110 and 111 is filled with the underfill 120, so that warpage of the wafer 130 can be sufficiently suppressed.

### [First Modification]

In the first embodiment described above, the grid-like patterning is performed by laser processing and surface modification, but the patterning process is not limited to this method. A manufacturing method in a first modification of the first embodiment is different from that of the first embodiment in that patterning is performed by resist film formation and plasma processing.

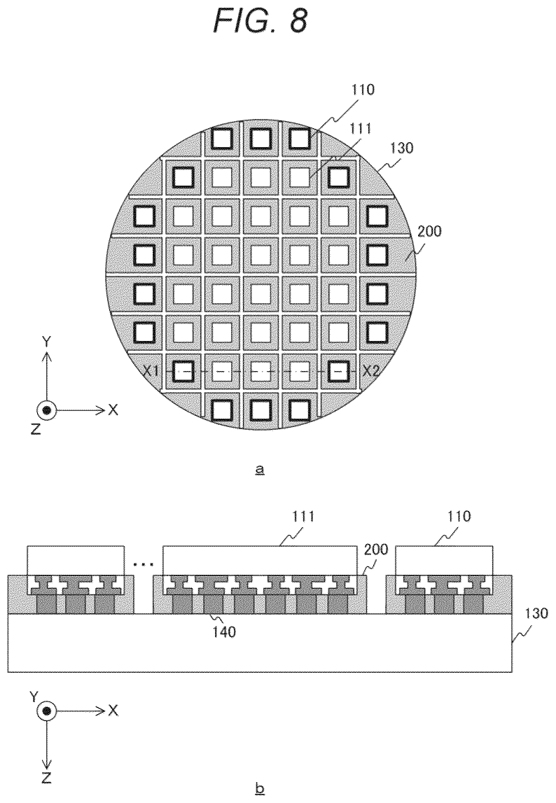

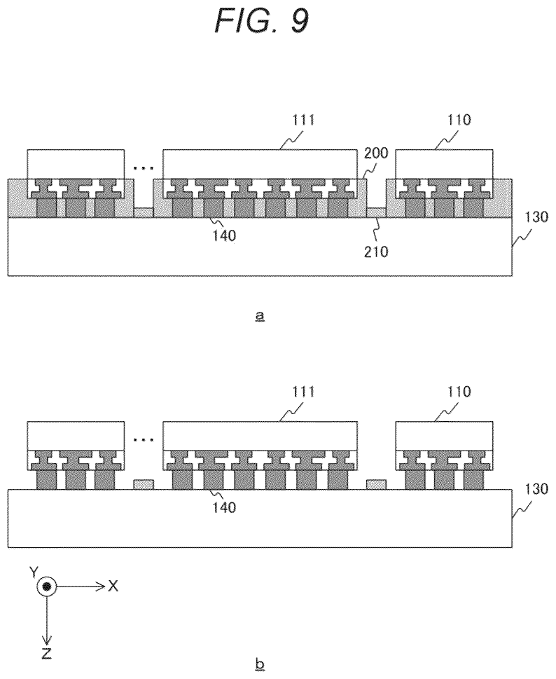

The patterning process in the first modification of the first embodiment will be described with reference to FIGS. 8 and 9.

As illustrated in FIG. 8, after die bonding, a resist 200 for protecting from plasma is formed between the integrated circuits 110 and 111 while a grid-like gap is left. In the drawing, a is an example of a plan view of the wafer 130, and b in the drawing is an example of a cross-sectional view taken along the line segment X1-X2 in a of the drawing.

Next, as illustrated in a of FIG. 9, a dam 210 is formed in a grid-like region without the resist 200 by plasma processing. Then, as illustrated in b of the drawing, the resist 200 is removed. Then, in a similar manner to the first embodiment, each process after the filling with the underfill 120 is executed.

As described above, according to the first modification of the first embodiment of the present technology, patterning can be performed by resist film formation and plasma processing.

### [Second Modification]

In the first embodiment described above, patterning is performed by laser processing and surface modification, but the patterning process is not limited to this method. The manufacturing method in the second modification of the first embodiment is different from that of the first embodiment in that patterning is performed by resist and lithography.

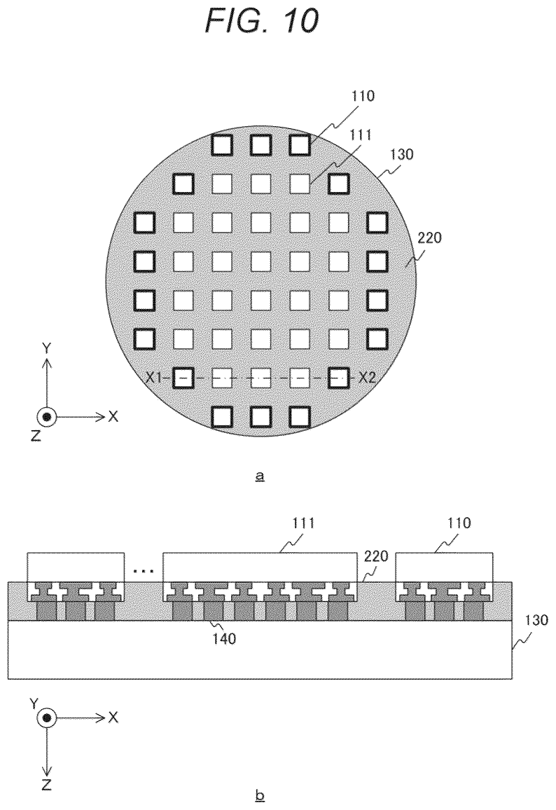

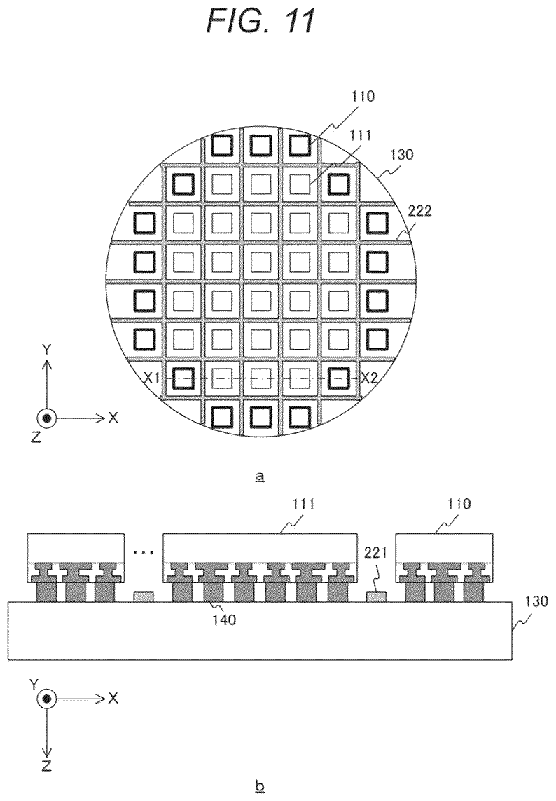

The patterning process in the second modification of the first embodiment will be described with reference to FIGS. 10 and 11.

As illustrated in FIG. 10, a photosensitive resist 220 is formed on the entire surface of the wafer 130 after die bonding. In the drawing, a is an example of a plan view of the wafer 130, and b in the drawing is an example of a cross-sectional view taken along the line segment X1-X2 in a of the drawing.

Then, as illustrated in FIG. 11, the resist 220 is removed by lithography while only the grid-like portion is left. The remaining portion is used as a dam 221. In a case where the resist 220 is a negative type, a mask having a grid-like gap is used. On the other hand, in a case where the resist 220 is a positive type, a grid-like mask is used. In the drawing, a is an example of a plan view of the wafer 130, and b in the drawing is an example of a cross-sectional view taken along the line segment X1-X2 in a of the drawing. Then, in a similar manner to the first embodiment, each process after the filling with the underfill 120 is executed.

As described above, according to the second modification of the first embodiment of the present technology, patterning can be performed by resist film formation and lithography.

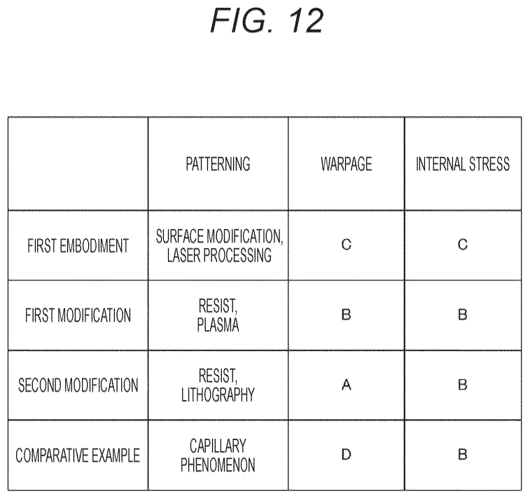

FIG. 12 is a view comparing the first embodiment of the present technology, each modification, and a comparative example.

In the drawing, warpage of the wafer 130 and internal stress were measured. A degree of warpage was evaluated in four stages of A, B, C, and D. In the wafer 130 of 300 millimeters (mm), warpage less than 50 micrometers (μm) was evaluated as “A”, and warpage equal to or greater than 50 and less than 100 micrometers (μm) was evaluated as “B”. Warpage equal to or greater than 100 and less than 250 micrometers (μm) was evaluated as “C”, and warpage equal to or greater than 250 micrometers (μm) was evaluated as “D”.

Further, internal stress was also evaluated in four stages of A, B, C, and D. In the wafer 130 of 300 millimeters (mm), internal stress less than 5 megapascals (MPa) was evaluated as “A”, and internal stress equal to or greater than 5 and less than 10 megapascals (MPa) was evaluated as “B”. Internal stress equal to or greater than 10 and less than 20 megapascals (MPa) was evaluated as “C”, and internal stress equal to or greater than 20 megapascals (MPa) was evaluated as “D”.

In the first embodiment in which patterning is performed by laser processing and surface modification, warpage in this case was evaluated as “C”, and internal stress was evaluated as “C”. In addition, in the first modification of the first embodiment in which patterning is performed by resist film formation and plasma processing, warpage in this case was evaluated as “B”, and internal stress was evaluated as “B”. In addition, in the second modification of the first embodiment in which patterning is performed by resist film formation and lithography, warpage in this case was evaluated as “A”, and internal stress was evaluated as “B”.

On the other hand, in the comparative example in which patterning is performed by capillary phenomenon, warpage in this case was evaluated as “D”, and internal stress was evaluated as “B”.

As illustrated in the drawing, according to the first embodiment and the first and second modifications thereof, it is possible to suppress warpage as compared with the comparative example. In addition, the internal stress can be suppressed to be equal to or less than that of the comparative example.

### 2. Second Embodiment

In the first embodiment described above, the grid-like dam 131 is formed, but this configuration requires a patterning process and a process of removing the dam 131. The manufacturing method of the second embodiment is different from that of the first embodiment in that the entire surface of the wafer 130 is filled with the underfill 120.

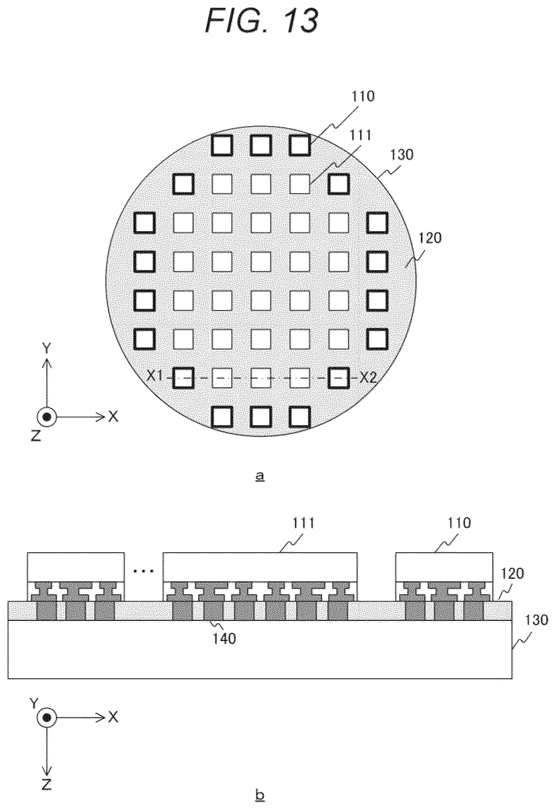

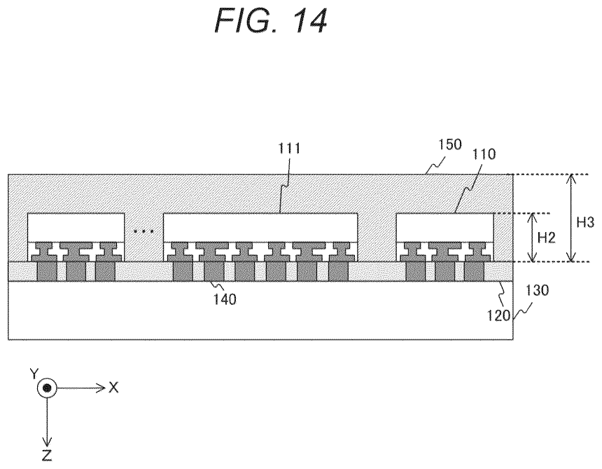

The manufacturing method in the second embodiment will be described with reference to FIG. 13 and FIG. 14.

As illustrated in FIG. 13, the entire surface of the wafer 130 is filled with the underfill 120 after die bonding. An upper surface of the underfill 120 is flat. In the drawing, a is an example of a plan view of the wafer 130, and b in the drawing is an example of a cross-sectional view taken along the line segment X1-X2 in a of the drawing. Then, the underfill 120 is cured by exposure.

Then, as illustrated in FIG. 14, the entire surface is sealed by a sealing material 150. Here, a height (in other words, a thickness) from a lower surface to an upper surface of each of the integrated circuits 110 and 111 is defined as H2. A height (in other words, a thickness) from a lower surface to an upper surface of the sealing material 150 is defined as H3. A ratio H3/H2, which is a ratio of the height (thickness) H3 of the sealing material 150 to the height (thickness) H2 of the integrated circuits, is preferably not less than 0.5.

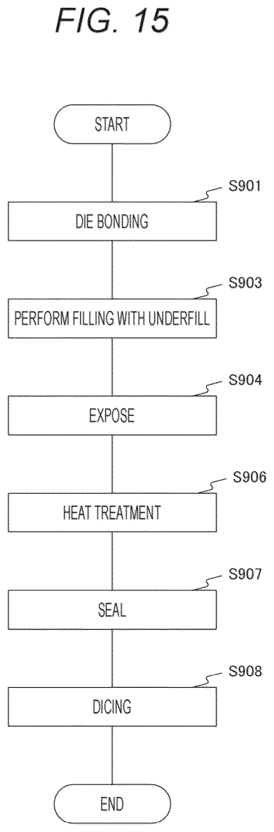

FIG. 15 is a flowchart indicating an example of a manufacturing method in the second embodiment of the present technology. The wafer 130 is die-bonded with a plurality of integrated circuits (step S901), and filling with the underfill 120 is performed (step S903). Then, the underfill 120 is cured by exposure (step S904). Subsequently, various kinds of heat treatment are performed (step S906). Then, a portion between the integrated circuits is sealed by the sealing material 150 (step S907), and dicing is performed (step S908).

As illustrated in the drawing, in a case where the entire surface of the wafer 130 is filled with the underfill 120, it is not necessary to form and remove the dam 131.

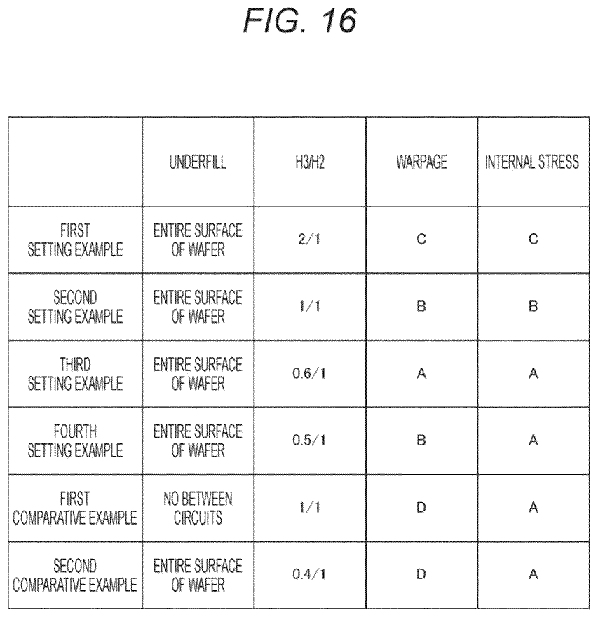

FIG. 16 is a view comparing respective characteristics between the second embodiment of the present technology and each comparative example. In the drawing, warpage and internal stress of the wafer 130 were evaluated in four stages of A, B, C, and D in a similar manner to the first embodiment.

In the second embodiment, the entire surface of the wafer 130 is filled with the underfill 120, and H3/H2, which is the ratio of the height (thickness) H3 of the sealing material 150 to the height (thickness) H2 of the integrated circuits, is set to equal to or higher than 0.5. In a first setting example of the second embodiment, H3/H2 was set to 2, and in a second setting example, H3/H2 was set to 1. Further, in a third setting example of the second embodiment, H3/H2 was set to 0.6, and in a fourth setting example, H3/H2 was set to 0.5.

Here, a case where the portion between the integrated circuits is not filled with the underfill 120, and H3/H2 is set to 1 is defined as a first comparative example. Further, a case where the entire surface of the wafer 130 is filled with the underfill 120, and H3/H2 is set to 0.4 is defined as a second comparative example.

In the first setting example, warpage was evaluated as “C”, and internal stress was evaluated as “C”. In the second setting example, warpage was evaluated as “B”, and internal stress was evaluated as “B”. In the third setting example, warpage was evaluated as “A”, and internal stress was evaluated as “A”. In the fourth setting example, warpage was evaluated as “B”, and internal stress was evaluated as “A”.

On the other hand, in the first and second comparative examples, warpage was evaluated as “D”, and internal stress was evaluated as “A”.

As illustrated in the drawing, by filling the entire surface of the wafer 130 with the underfill 120 and setting H3/H2 to equal to or higher than 0.5, warpage can be suppressed as compared with the first and second comparative examples.

### 3. Third Embodiment

In the second embodiment in which the entire surface of the wafer 130 is filled with the underfill 120, a cross-sectional shape of the underfill 120 is preferably made a fillet shape. The manufacturing method in the third embodiment is different from that in the second embodiment in that the cross-sectional shape of the underfill 120 is made a fillet shape.

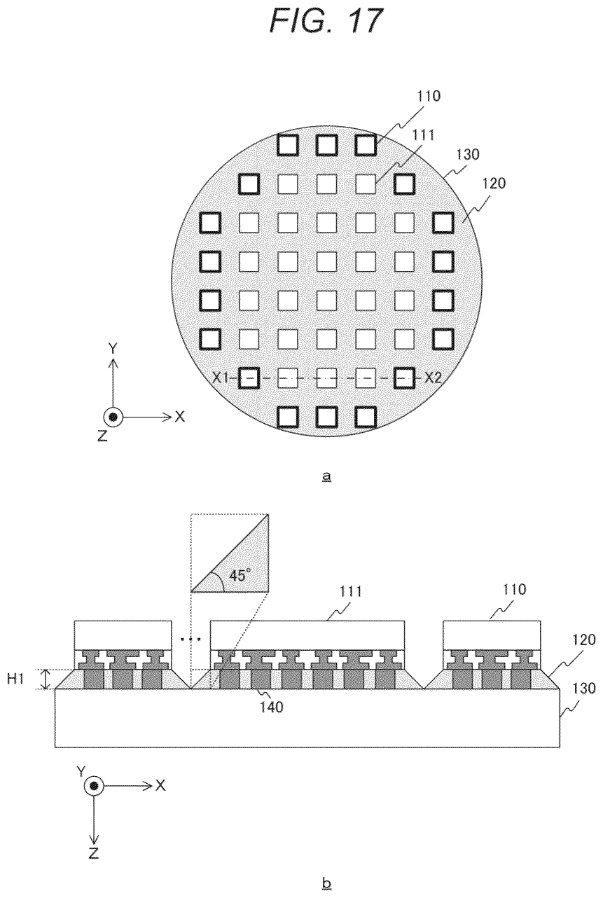

FIG. 17 is a view illustrating an example of a plan view and a cross-sectional view of the wafer 130 at the time of forming the underfill in the third embodiment of the present technology. In the drawing, a is an example of a plan view of the wafer 130, and b in the drawing is an example of a cross-sectional view taken along the line segment X1-X2 in a of the drawing.

As illustrated in a of the drawing, in the third embodiment, the entire surface of the wafer 130 is filled with the underfill 120. In addition, as illustrated in b of the drawing, the underfill 120 in the vicinity of the outer periphery of each of the integrated circuits 110 and 111 has a cross-sectional shape expanding like a tube (in other words, the fillet shape) when viewed from the X-axis direction or the Y-axis direction. A contact angle, which is an angle between a slope of the underfill 120 and a substrate plane of the wafer 130, is adjusted to, for example, approximately 45°. As a result of the fillet shape, an effect of suppressing warpage can be further improved as compared with the second embodiment.

Further, if the height of the underfill 120 from the substrate plane of the wafer 130 is defined as H1, the height H1 is adjusted to be substantially equal to the wafer-circuit distance H0. Thus, the underfill 120 does not closely adhere to the side walls of the integrated circuits 110 and 111.

Note that in the third embodiment, the entire surface of the wafer 130 is filled with the underfill 120 without patterning, but patterning can be performed as in the first embodiment. As described above, according to the third embodiment of the present technology, the cross-sectional shape of the underfill 120 is made a fillet shape, so that an effect of suppressing warpage can be further improved.

### [First Modification]

In the third embodiment described above, a portion along the outer peripheries of the integrated circuits is filled with the underfill 120, but a method in which a portion along part of the outer peripheries is filled with the underfill 120 can be used. A manufacturing method in a first modification of the third embodiment is different from that of the third embodiment in that a portion along part of the outer peripheries of the integrated circuits is filled with the underfill 120.

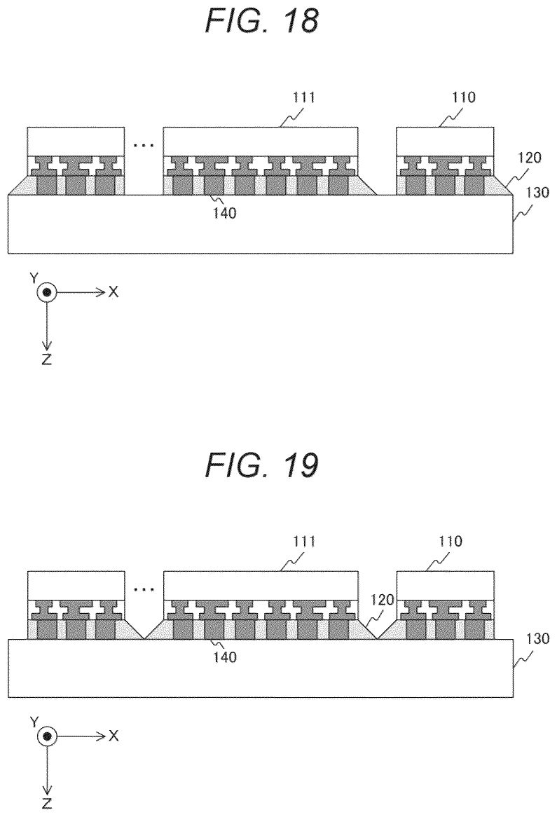

FIG. 18 is a view illustrating an example of a cross-sectional view of the wafer 130 at the time of forming the underfill 120 in the first modification of the third embodiment of the present technology. As illustrated in the drawing, in the first modification of the third embodiment, a portion along part (such as three of four sides) of the outer peripheries of the integrated circuits is filled with the underfill 120. For example, a right side of a leftmost integrated circuit 110 is not filled with the underfill 120, and a left side of a rightmost integrated circuit 110 is not filled with the underfill 120. As a result, internal stress can be reduced as compared with the third embodiment.

As described above, according to the first modification of the third embodiment of the present technology, a portion along part of the outer peripheries of the integrated circuits is filled with the underfill 120, so that internal stress can be reduced as compared with the third embodiment.

### [Second Modification]

In the third embodiment described above, an outer side of the integrated circuits 110 adjacent to the outer periphery of the wafer 130 is also filled with the underfill 120, but a method in which the outer side is not filled with the underfill 120 can also be used. The manufacturing method in the second modification of the third embodiment is different from that of the third embodiment in that an outer side of the integrated circuits 110 is not filled with the underfill 120.

FIG. 19 is a view illustrating an example of a cross-sectional view of the wafer 130 at the time of forming the underfill 120 in the second modification of the third embodiment of the present technology. As illustrated in the drawing, in the second modification of the third embodiment, the outer peripheries of the inner integrated circuits 111 and the inner side of the integrated circuits 110 adjacent to the outer periphery of the wafer 130 are filled with the underfill 120. On the other hand, the outer side of the integrated circuits 110 is not filled with the underfill 120. For example, a left side of the leftmost integrated circuit 110 and a right side of the rightmost integrated circuit 110 are not filled with the underfill 120. As a result, internal stress can be reduced as compared with the third embodiment.

Note that the integrated circuits 110 are an example of inner side integrated circuits described in the claims, and the integrated circuits 111 are an example of outer side integrated circuits described in the claims.

As described above, according to the second modification of the third embodiment of the present technology, the outer side of the integrated circuits 110 is not filled with the underfill 120, so that internal stress can be reduced as compared with the third embodiment.

### [Third Modification]

In the third embodiment described above, the contact angle is set to 45°, but the present invention is not limited to this angle. A manufacturing method in a third modification of the third embodiment is different from that of the third embodiment in that the contact angle is changed.

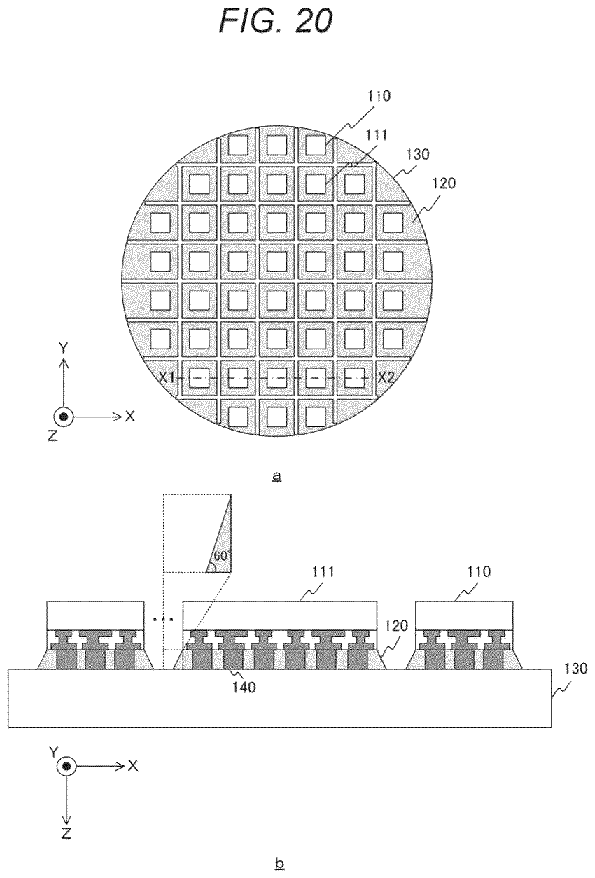

FIG. 20 is a view illustrating an example of a plan view and a cross-sectional view of the wafer at the time of forming the underfill 120 in the third modification of the third embodiment of the present technology. In the drawing, a is an example of a plan view of the wafer 130, and b in the drawing is an example of a cross-sectional view taken along the line segment X1-X2 in a of the drawing.

As illustrated in a of the drawing, in the third modification of the third embodiment, a portion except for a grid-like gap is filled with the underfill 120 by patterning. Further, as illustrated in b of the drawing, the contact angle is adjusted to, for example, approximately 60°.

In the patterning process, a region to be filled with the underfill 120 is separated for each integrated circuit by the grid-like dam 131, so that each region can be uniformly filled with the underfill 120.

As described above, according to the third modification of the third embodiment of the present technology, the contact angle is set to 60°, so that patterning can be performed. As a result, filling with the underfill 120 can be uniformly performed.

### [Fourth Modification]

In the third embodiment described above, the contact angle is set to 45°, but the present invention is not limited to this angle. A manufacturing method in a fourth modification of the third embodiment is different from that of the third embodiment in that the contact angle is changed.

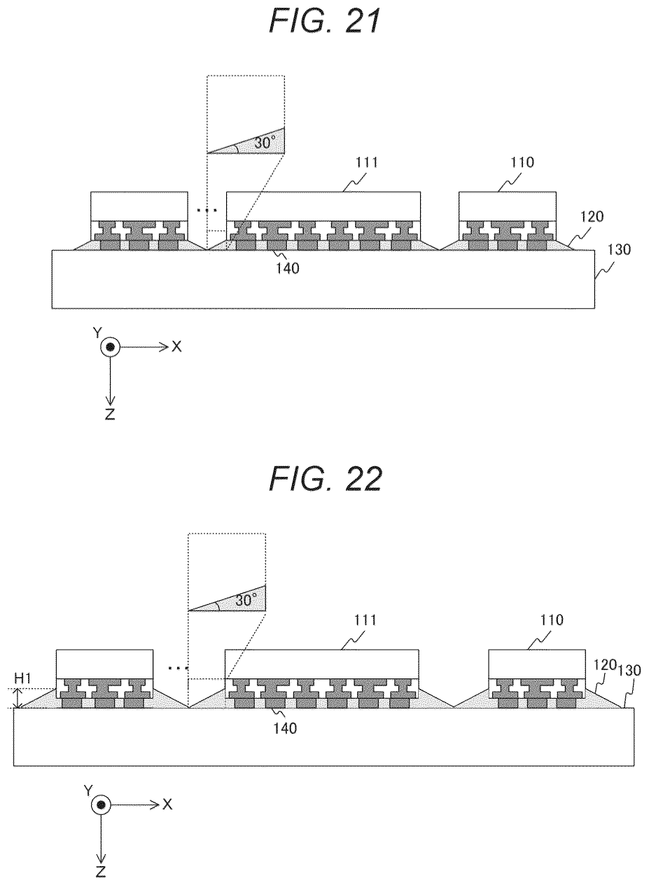

FIG. 21 is a view illustrating an example of a cross-sectional view of the wafer 130 at the time of forming the underfill 120 in the fourth modification of the third embodiment of the present technology. As illustrated in the drawing, in the fourth modification of the third embodiment, the contact angle is adjusted to approximately 30°. As a result, an effect of suppressing warpage can be improved as compared with the case of 45°.

As described above, according to the fourth modification of the third embodiment of the present technology, the contact angle is adjusted to approximately 30°, so that the effect of suppressing warpage can be improved.

### [Fifth Modification]

In the third embodiment described above, filling with the underfill 120 is performed so that the underfill 120 does not closely adhere to the side surfaces of the integrated circuits 110 and 111, but the underfill 120 may closely adhere to part of the side walls. A manufacturing method in a fifth modification of the third embodiment is different from that of the third embodiment in that the underfill 120 closely adheres to part of the side walls of the integrated circuits 110 or 111.

FIG. 22 is a view illustrating an example of a cross-sectional view of the wafer 130 at the time of forming the underfill 120 in the fifth modification of the third embodiment of the present technology. As illustrated in the drawing, in the fifth modification of the third embodiment, the contact angle is adjusted to approximately 30°.

In addition, the height H1 of a vertex of the fillet shape of the underfill 120 is assumed to be higher than the wafer-circuit distance H0. Thus, the underfill 120 closely adheres to part of the side walls of the integrated circuits 110 or 111. As a result, the effect of suppressing warpage can be improved as compared with a case where the underfill 120 does not closely adhere to the side walls.

As described above, according to the fifth modification of the third embodiment of the present technology, the underfill 120 closely adheres to part of the side walls of the integrated circuits 110 or 111, so that the effect of suppressing warpage can be improved.

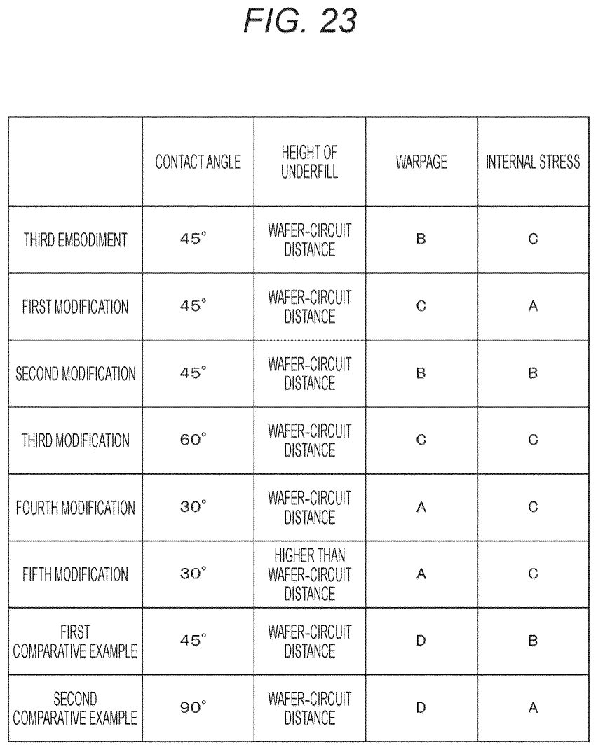

FIG. 23 is a view comparing respective characteristics between the third embodiment of the present technology and each comparative example. In the drawing, warpage and internal stress of the wafer 130 were evaluated in four stages of A, B, C, and D in a similar manner to the first embodiment.

In addition, a case where a cross-section of the underfill 120 has a fillet shape having a contact angle of 45° and only the outer peripheral portion of the wafer 130 is filled with the underfill 120 is defined as a first comparative example. In addition, a case where the contact angle of the underfill 120 is set to 90° (in other words, a fillet shape is not formed) and only the outer peripheral portion of the wafer 130 is filled with the underfill 120 is defined as a second comparative example.

In the third embodiment, warpage was evaluated as “B”, and internal stress was evaluated as “C”. In the first modification of the third embodiment, warpage was evaluated as “C”, and internal stress was evaluated as “A”. In the second modification of the third embodiment, warpage was evaluated as “B”, and internal stress was evaluated as “B”. In the third modification of the third embodiment, warpage was evaluated as “C”, and internal stress was evaluated as “C”. In the fourth modification of the third embodiment, warpage was evaluated as “A”, and internal stress was evaluated as “C”. In the fifth modification of the third embodiment, warpage was evaluated as “A”, and internal stress was evaluated as “C”.

On the other hand, in the first comparative example, warpage was evaluated as “D”, and internal stress was evaluated as “B”. Further, in the second comparative example, warpage was evaluated as “D”, and internal stress was evaluated as “A”.

As illustrated in the drawing, by filling a portion along the outer periphery of each of the integrated circuits with the underfill 120 in a fillet shape, warpage can be suppressed as compared with the first and second comparative examples.

### 4. Fourth Embodiment

In the first embodiment, filling with the underfill 120 is performed after patterning, but if an injection location of the underfill 120 is narrow, it may be difficult to perform filling with the underfill 120. A manufacturing method in a fourth embodiment is different from that in the first embodiment in that filling with the underfill 120 is made easier.

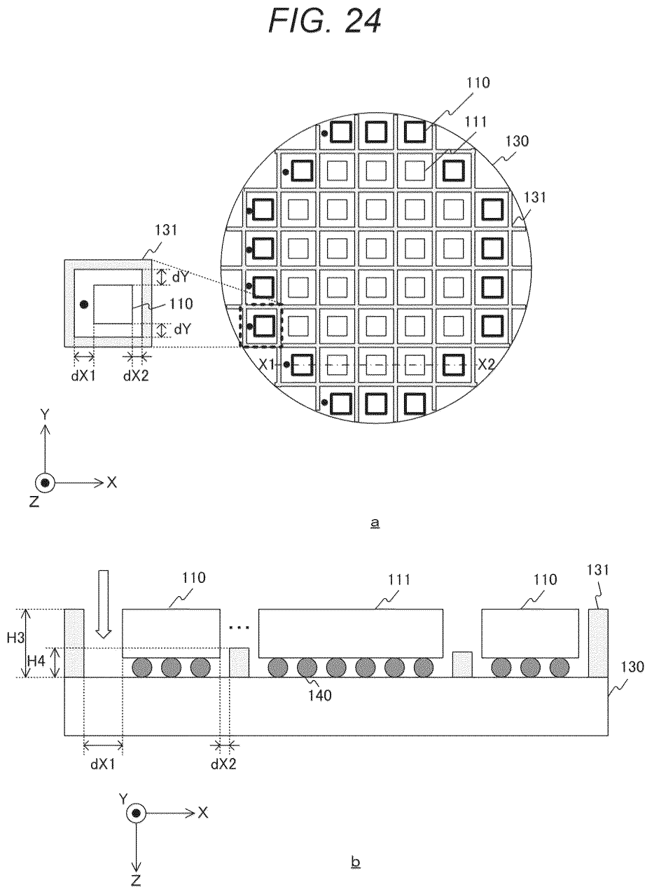

FIG. 24 is a view illustrating an example of a plan view and a cross-sectional view of the wafer 130 at the time of patterning in the fourth embodiment of the present technology. In the drawing, a is an example of a plan view of the wafer 130, and b in the drawing is an example of a cross-sectional view taken along the line segment X1-X2 in a of the drawing.

In a subsequent process, in a case where filling with the underfill 120 is performed while a right end of the wafer 130 is inclined to be lower than a left end, the underfill 120 is injected from an upper portion of the left end of the wafer 130. Note that filling with the underfill 120 can be performed from a central portion of the wafer 130, and the underfill 120 can be spread by a centrifugal force by rotating the wafer 130. In this case, the central portion is the injection location.

A black circle at the left end of a in the drawing indicates the injection location of the underfill 120. Among rows of the integrated circuits 110 and 111 arranged in the X-axis direction, filling with the underfill 120 is performed from the left side of the leftmost integrated circuit 110. Each of the integrated circuits 110 has a rectangular shape when viewed from the Z-axis direction, and a region surrounded by the dam 131 also has a rectangular shape. Patterning is performed so that a distance dX1 from a left side of the four sides of the leftmost integrated circuit 110 to the inner wall of the dam 131 becomes longer than distances dX2 and dY from the remaining three sides to the inner wall of the dam 131. On the other hand, in the integrated circuits other than the leftmost integrated circuit, patterning is performed so that distances from the four sides to the inner wall of the dam 131 are substantially the same.

Further, in b of the drawing, an arrow indicates a direction in which the underfill 120 is injected. Patterning is performed so that H3, which is the height of the left end and the right end of the dam 131 becomes higher than H4, which is the height of the dam 131 inside them.

As illustrated in the drawing, as a result of a distance from the side corresponding to the injection location to the inner wall of the dam 131 being made longer, it is possible to widen the injection location of the underfill 120 accordingly. In addition, as a result of the height of the left end and the right end of the dam 131 being increased, it is possible to prevent the underfill 120 from flowing out to an unnecessary portion and to promote filling to the right end far from the injection location.

Note that each modification of the first embodiment, the third embodiment and each modification of the third embodiment can be applied to the fourth embodiment. The similar applies to each modification of a fourth embodiment described later.

In addition, the same material as the sealing material 150 can be used as the material of the dam. This eliminates the need for a process of removing the dam. The similar applies to modifications of the fourth embodiment described later.

As described above, according to the fourth embodiment of the present technology, the distance from the side corresponding to the injection location to the inner wall of the dam 131 is made longer, so that the underfill 120 can be easily injected.

### [First Modification]

In the fourth embodiment described above, the distance from the side corresponding to the injection location to the inner wall of the dam 131 is made longer, but a U-shaped recess can also be formed at the injection location. A manufacturing method in a first modification of the fourth embodiment is different from that of the fourth embodiment in that a planar shape of the dam 131 is changed.

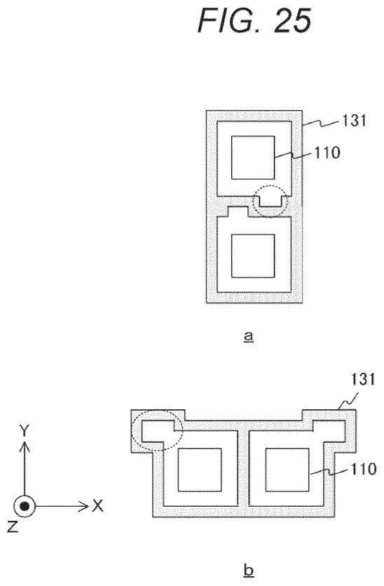

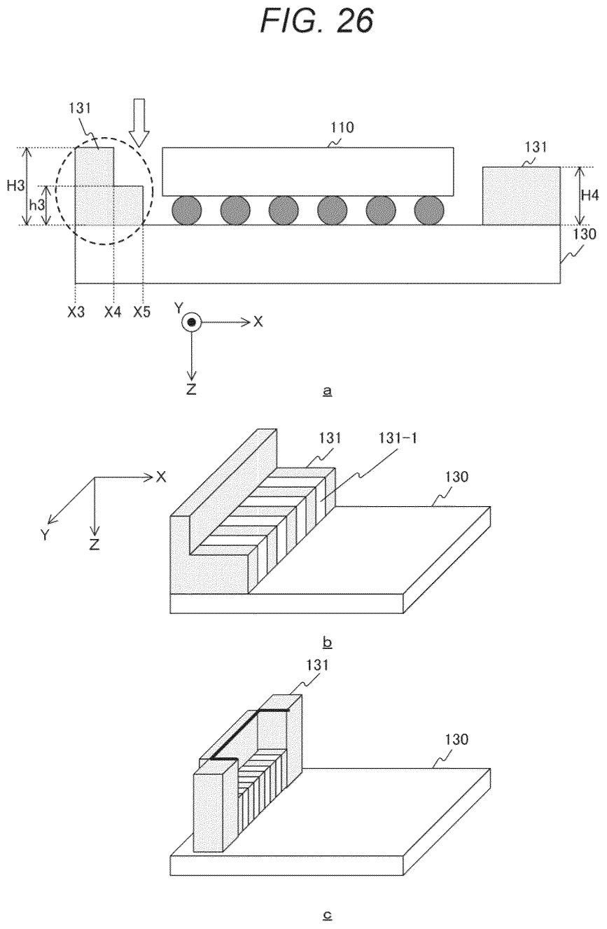

FIG. 25 is a view illustrating an example of a plan view of the dam 131 in the first modification of the fourth embodiment of the present technology.

As illustrated in a of the drawing, in the first modification of the fourth embodiment, a U-shaped recess protruding outward is provided in part of one side among four sides of the region surrounded by the dam 131 when viewed from the Z-axis direction. A portion surrounded by a dotted line in a of the drawing indicates a U-shaped recess. The underfill 120 is injected into this recess.

Note that as illustrated in b of the drawing, the U-shaped recess can be formed in the corner.

As described above, according to the first modification of the fourth embodiment of the present technology, the U-shaped recess is formed in the region surrounded by the dam 131, so that the underfill 120 can be easily injected.

### [Second Modification]

In the fourth embodiment described above, the distance from the side corresponding to the injection location to the inner wall of the dam 131 is made longer, but a step may be provided in part of the dam 131. A manufacturing method in a second modification of the fourth embodiment is different from that in the fourth embodiment in that a step is provided in the dam 131.

FIG. 26 is a view illustrating an example of the wafer 130 and the dam 131 in the second modification of the fourth embodiment of the present technology. In the drawing, a illustrates a cross-sectional view of the left end of the wafer 130. b and c in the drawing are perspective views of the left end of the dam 131.

As illustrated in a of the drawing, in the second modification of the fourth embodiment, a step is formed in the vicinity of the left end of the dam 131. For example, a height of the region from a coordinate X3 of the left end to a coordinate X4 of the inner side is H3, and a height of the region from the coordinate X4 to a coordinate X5 of the inner side is h3 lower than H3. Filling with the underfill 120 is performed from this step.

As illustrated in b of the drawing, a predetermined number of slits can be formed along a direction in which the underfill 120 is allowed to permeate in a portion of the step.

In addition, as illustrated in c of the drawing, a U-shaped recess as viewed from the Z-axis direction may be formed in the dam 131, and a step can be provided in a portion of the recess.

Note that, in b and c of the drawing, a slit is formed in the dam 131, but a shape without a slit can be used.

As described above, according to the second modification of the fourth embodiment of the present technology, the step is provided in part of the dam 131, so that filling of the underfill 120 can be promoted.

### [Third Modification]

In the fourth embodiment described above, the distance from the side corresponding to the injection location to the inner wall of the dam 131 is made longer, but a slope may be formed in part of the dam 131. A manufacturing method in a third modification of the fourth embodiment is different from that in the fourth embodiment in that a slope is formed in the dam 131.

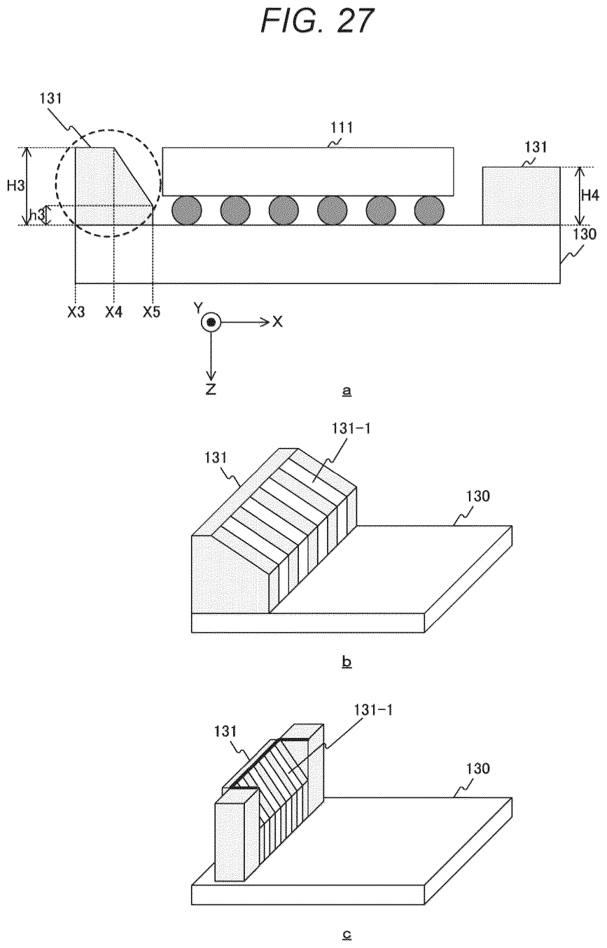

FIG. 27 is a view illustrating an example of the wafer 130 and the dam 131 in the third modification of the fourth embodiment of the present technology. In the drawing, a illustrates a cross-sectional view of the left end of the wafer 130. b and c in the drawing are perspective views of the left end of the dam 131.

As illustrated in a of the drawing, in the third modification of the fourth embodiment, a slope is formed in the vicinity of the left end of the dam 131. For example, a height of the region from a coordinate X3 of the left end to a coordinate X4 of the inner side is H3, and a height at a coordinate X5 of the inner side is h3 lower than H3. A height of the region from the coordinates X3 to X4 gradually changes to form a slope. This slope is filled with the underfill 120.

As illustrated in b of the drawing, a predetermined number of slits can be formed at a portion of the slope along a direction in which the underfill 120 is allowed to permeate.

In addition, as illustrated in c of the drawing, a U-shaped recess as viewed from the Z-axis direction may be formed in the dam 131, and a slope may be provided in a portion of the recess.

Note that, in b and c of the drawing, a slit is formed in the dam 131, but a shape without a slit can be used.

As described above, according to the third modification of the fourth embodiment of the present technology, the slope is provided in part of the dam 131, so that filling of the underfill 120 can be promoted.

### [Fourth Modification]

In the fourth embodiment described above, the distance from the side corresponding to the injection location to the inner wall of the dam 131 is made longer, but a trench may be formed in the wafer 130. A manufacturing method in a fourth modification of the fourth embodiment is different from that of the fourth embodiment in that a trench is formed in the wafer 130.

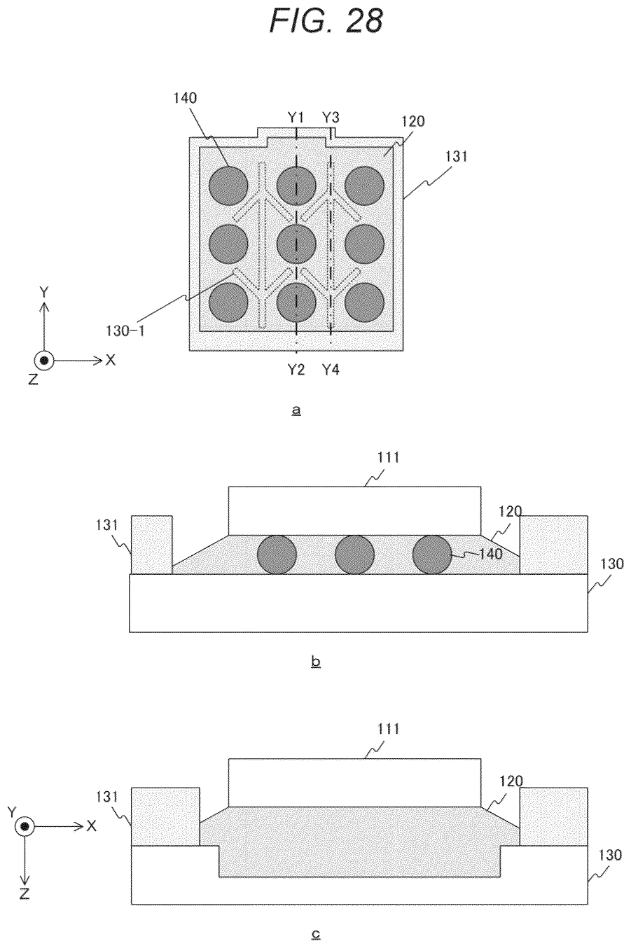

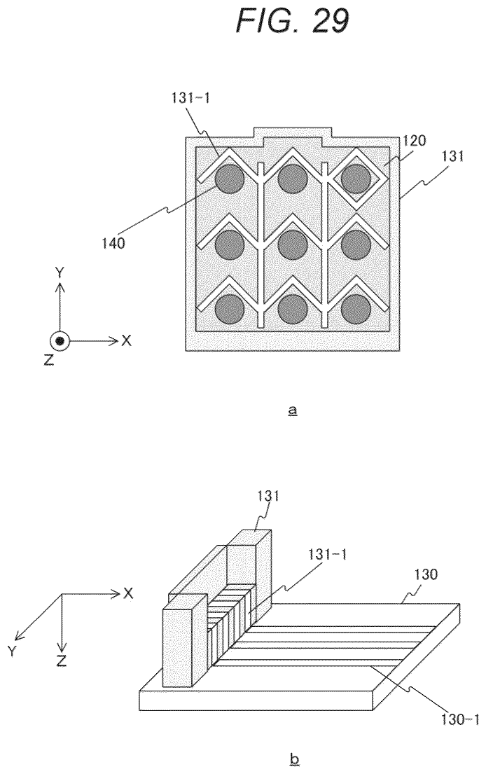

FIG. 28 is a view illustrating an example of a top view and a cross-sectional view of the wafer 130 at the time of filling with the underfill 120 in the fourth modification of the fourth embodiment of the present technology.

In the drawing, a indicates a region around one integrated circuit on an upper surface of the wafer 130. In this top view, the integrated circuit is omitted. A U-shaped recess is formed in part of the dam 131, and a trench 130-1 is formed on the upper surface of the wafer 130. A dotted line in a of the drawing indicates outline of the trench. A line segment Y1-Y2 in a of the drawing does not pass through the trench 130-1, and a line segment Y3-Y4 passes through the trench 130-1.

In the drawing, b illustrates a cross-sectional view when the wafer 130 is cut along the line segment Y1-Y2 in a of the drawing. In the drawing, c illustrates a cross-sectional view when the wafer 130 is cut along the line segment Y3-Y4 in a of the drawing.

As illustrated in c of the drawing, the trench 130-1 is formed immediately below the integrated circuit 111. The trench 130-1 is formed along a filling direction of the underfill 120, and part thereof branches into a branch shape. The filling with the underfill 120 is promoted by such a trench 130-1.

Note that, as illustrated in a of FIG. 29, the number of branches of the trench 130-1 may be increased, or the trench 130-1 may be formed so as to surround an electrode 140.

Further, as illustrated in b of the drawing, the second modification of the fourth embodiment can be further applied.

As described above, according to the fourth embodiment of the fourth embodiment of the present technology, the trench is formed in the wafer 130, so that filling with the underfill 120 can be promoted.

### 5. Fifth Embodiment

In the first embodiment described above, the wafer 130 is divided into a predetermined number of semiconductor chips. A semiconductor package is obtained by mounting these semiconductor chips on a substrate. In a manufacturing method in a fifth embodiment, the semiconductor chip manufactured in the first embodiment is mounted on a substrate.

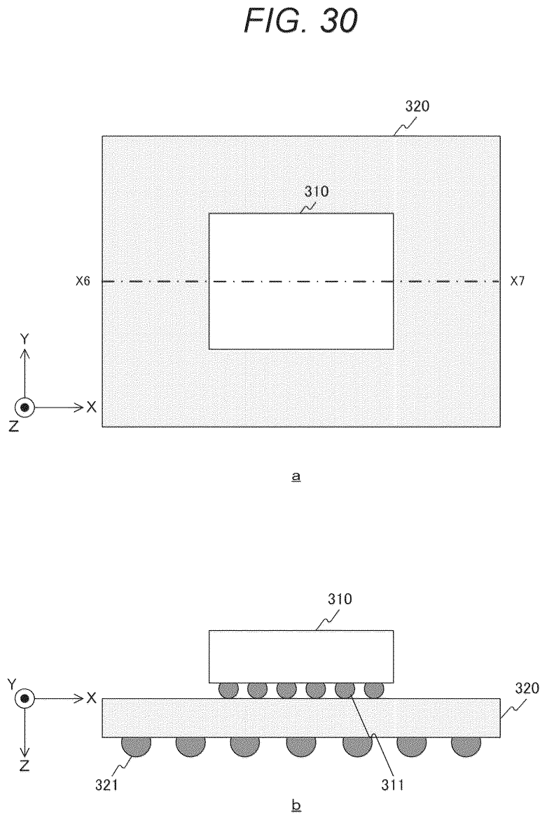

A manufacturing method after dicing in the fifth embodiment will be described with reference to FIGS. 30 to 33.

As illustrated in FIG. 30, the semiconductor chip 310 obtained by dicing is mounted on the substrate 320 in a fiber up manner. In the drawing, a illustrates a plan view of a substrate 320, and b illustrates a cross-sectional view of the substrate 320 taken along a line segment X6-X7 in the drawing.

As illustrated in b of the drawing, the semiconductor chip 310 is bonded to an upper surface of the substrate 320 by solder balls 311. Further, a predetermined number of solder balls 321 are formed on a lower surface of the substrate 320.

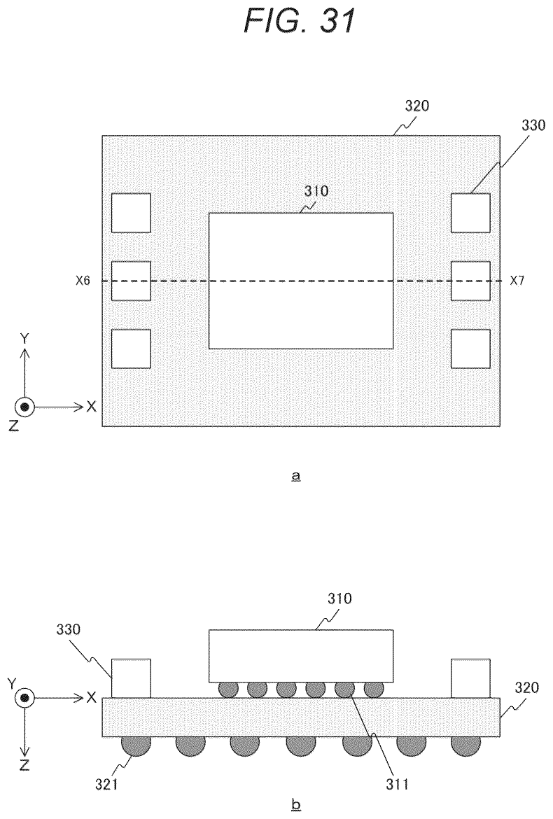

Next, as illustrated in FIG. 31, a predetermined number of passive components 330 are arranged and mounted around the semiconductor chip 310. In the drawing, a illustrates a plan view of a substrate 320, and b illustrates a cross-sectional view of the substrate 320 taken along the line segment X6-X7 in the drawing.

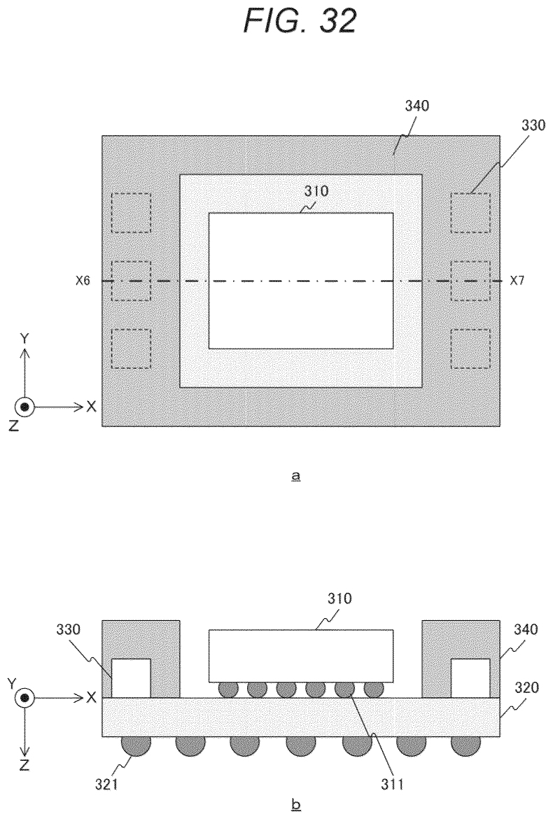

Then, as illustrated in FIG. 32, a mold resin 340 is formed around the semiconductor chip 310, and the passive components 330 are sealed by the mold resin 340. In the drawing, a illustrates a plan view of a substrate 320, and b illustrates a cross-sectional view of the substrate 320 taken along the line segment X6-X7 in the drawing.

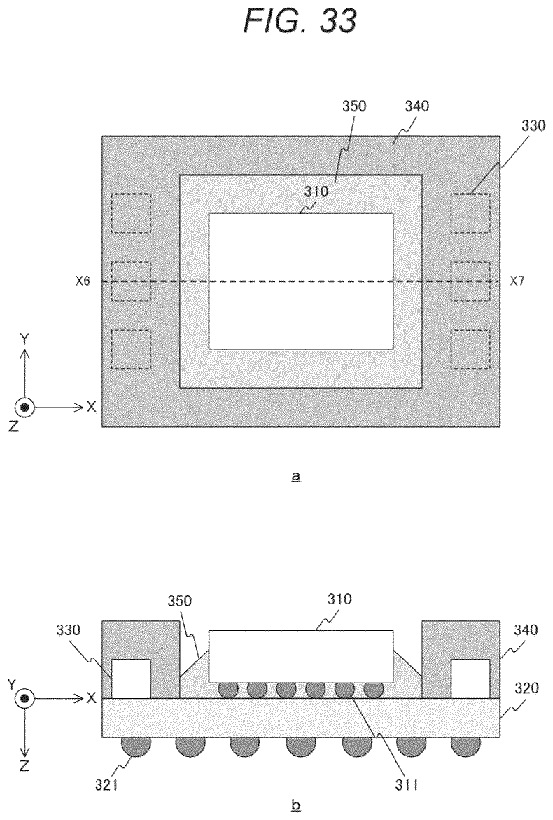

Next, as illustrated in FIG. 33, a portion between the mold resin 340 and the semiconductor chip 310 is filled with an underfill 350. Thus, a semiconductor package is manufactured. In the drawing, a illustrates a plan view of a substrate 320, and b illustrates a cross-sectional view of the substrate 320 taken along the line segment X6-X7 in the drawing.

As illustrated in b of the drawing, the underfill 350 crawls up to an inner wall of the mold resin 340 and has a fillet cross-sectional shape.

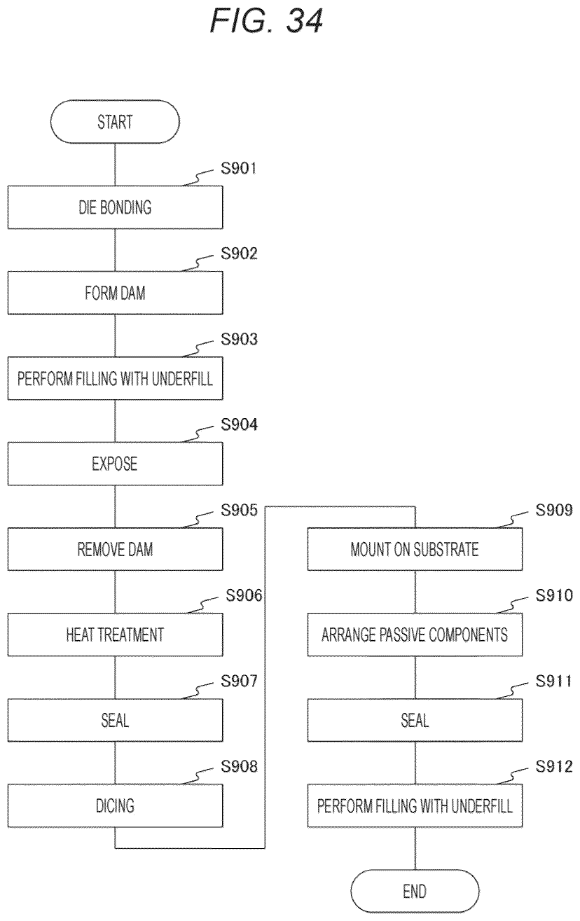

FIG. 34 is a flowchart indicating an example of the manufacturing method in the fifth embodiment of the present technology. In the fifth embodiment, steps S901 to S908 are similar to those in the first embodiment.

After dicing (step S908), the semiconductor chip 310 is mounted on the substrate 320 (step S909). Then, the passive components 330 are arranged (step S910), and these components are sealed by the mold resin 340 (step S911). Subsequently, filling with the underfill 120 is performed (step S912). Through these steps, a semiconductor package is manufactured. Note that the underfill 120 used in step S903 is an example of a first underfill recited in the claims, and the underfill 350 used in step S912 is an example of a second underfill recited in the claims.

Here, a manufacturing method in which the passive components 330 are not sealed by the mold resin 340, and the mold resin 340 is provided between the semiconductor chip 310 and the passive components 330 is assumed as a comparative example.

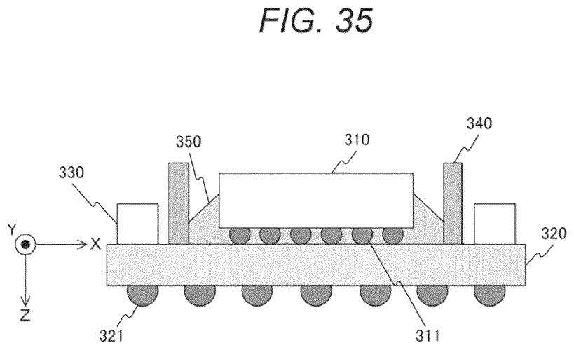

FIG. 35 is a cross-sectional view illustrating an example a semiconductor package in the comparative example. In the comparative example illustrated in the drawing, it is necessary to remove the mold resin 340 by potassium hydroxide (KOH), or the like, after filling with the underfill 120. In this event, the underfill 350 may be damaged. In addition, man-hours increase by an amount corresponding to a process of removing the mold resin 340. Furthermore, it is necessary to apply the mold resin 340 to a narrow area, which lowers productivity.

On the other hand, in a case where the passive components 330 are sealed by the mold resin 340, unlike the comparative example, the process of removing the mold resin 340 is unnecessary, and man-hours can be reduced. In addition, sealing is performed by the mold resin 340, and thus, the underfill 350 does not come into contact with the passive components 330, and a height of the fillet shape of the underfill 120 can be increased to the same extent as in the comparative example. Further, it is not necessary to form the mold resin 340 in a narrow area, so that productivity is improved.

Note that the second, third and fourth embodiments, and respective modifications of the first to the fourth embodiments can be applied to the fifth embodiment. The similar applies to each modification of the fifth embodiment described later.

As described above, according to the fifth embodiment of the present technology, the passive components 330 are sealed by the mold resin 340, so that it is possible to reduce man-hours and improve productivity.

### [First Modification]

In the fifth embodiment described above, the passive components 330 are sealed by the mold resin 340, but it is difficult to further reduce man-hours. A manufacturing method in a first modification of the fifth embodiment is different from that of the fifth embodiment in that the substrate 320 having a cavity structure is used.

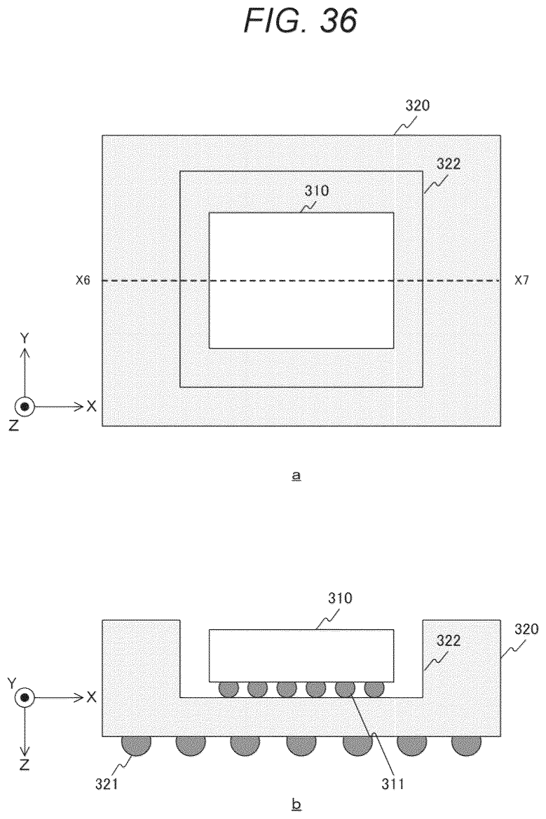

A manufacturing method after dicing in the first modification of the fifth embodiment will be described with reference to FIGS. 36 to 38.

As illustrated in FIG. 36, the semiconductor chip 310 obtained by dicing is mounted in the cavity of the substrate 320 in a face-up manner. In the drawing, a illustrates a plan view of a substrate 320, and b illustrates a cross-sectional view of the substrate 320 taken along the line segment X6-X7 in the drawing.

As illustrated in a and b of the drawing, a cavity 322 having a concave cross-sectional shape is formed on an upper surface of the substrate 320. The semiconductor chip 310 is mounted inside the cavity 322.

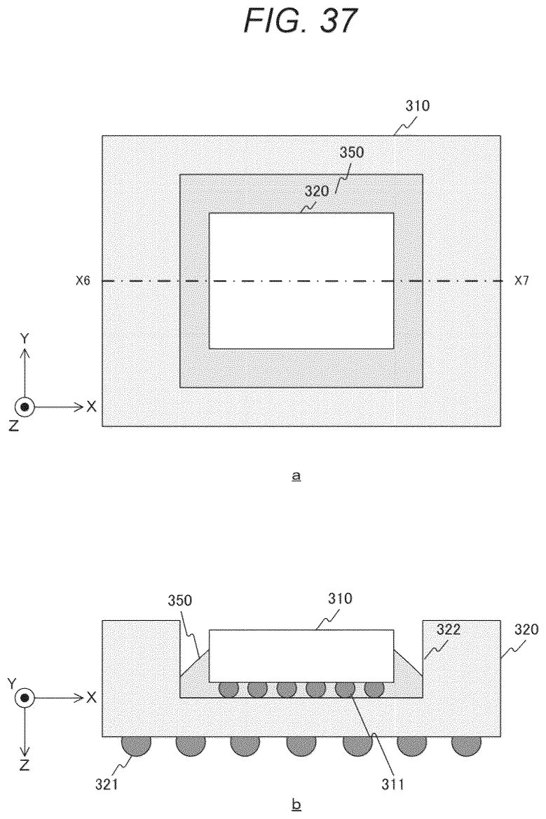

Next, as illustrated in FIG. 37, a portion between the semiconductor chip 310 and an inner wall of the cavity 322 is filled with an underfill 350. In the drawing, a illustrates a plan view of a substrate 320, and b illustrates a cross-sectional view of the substrate 320 taken along the line segment X6-X7 in the drawing.

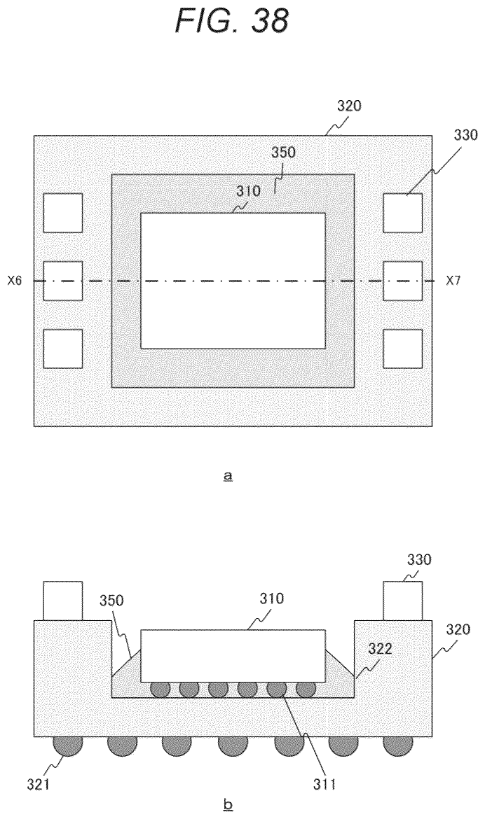

Then, as illustrated in FIG. 38, a predetermined number of passive components 330 are arranged around the cavity 322 on an upper surface of the substrate 320. In the drawing, a illustrates a plan view of a substrate 320, and b illustrates a cross-sectional view of the substrate 320 taken along the line segment X6-X7 in the drawing.

For example, a width equal to or greater than 1 millimeter (mm) can be ensured around the cavity 322. Thus, for example, passive components 330 having 0603 size of 0.6×0.6 millimeters (mm) can be mounted.

As described above, according to the first modification of the fifth embodiment of the present technology, the substrate 320 having the cavity structure is used, so that a process of forming the mold resin 340 becomes unnecessary.

### [Second Modification]

In the fifth embodiment described above, the passive components 330 are sealed by the mold resin 340, but a component that cannot be incorporated cannot be further mounted. A manufacturing method in a second modification of the fifth embodiment is different from that of the fifth embodiment in that a component is incorporated in a substrate and a component that cannot be incorporated in the substrate is further mounted on the surface.

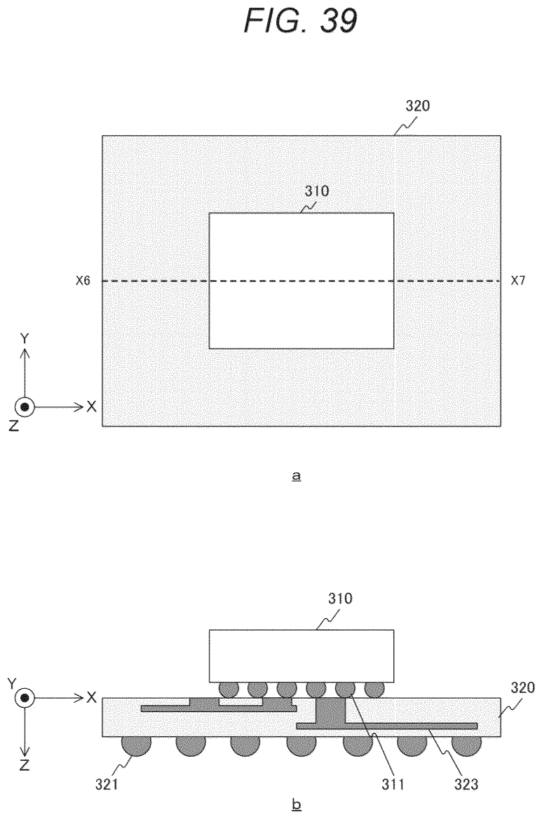

A manufacturing method after dicing in the second modification of the fifth embodiment will be described with reference to FIGS. 39 to 43.

As illustrated in FIG. 39, the semiconductor chip 310 obtained by dicing is mounted on the substrate 320 in a fiber up manner. In the drawing, a illustrates a plan view of a substrate 320, and b illustrates a cross-sectional view of the substrate 320 taken along the line segment X6-X7 in the drawing.

As illustrated in b of the drawing, a printed component 323 such as a capacitor or an inductor is formed by printing and incorporated in the substrate 320.

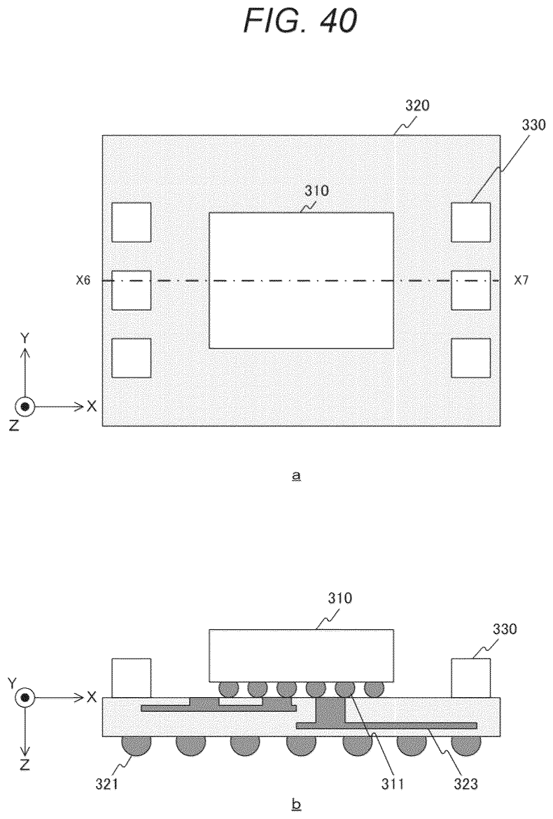

Next, as illustrated in FIG. 40, a predetermined number of passive components 330 are arranged around the semiconductor chip 310. In the drawing, a illustrates a plan view of a substrate 320, and b illustrates a cross-sectional view of the substrate 320 taken along the line segment X6-X7 in the drawing.

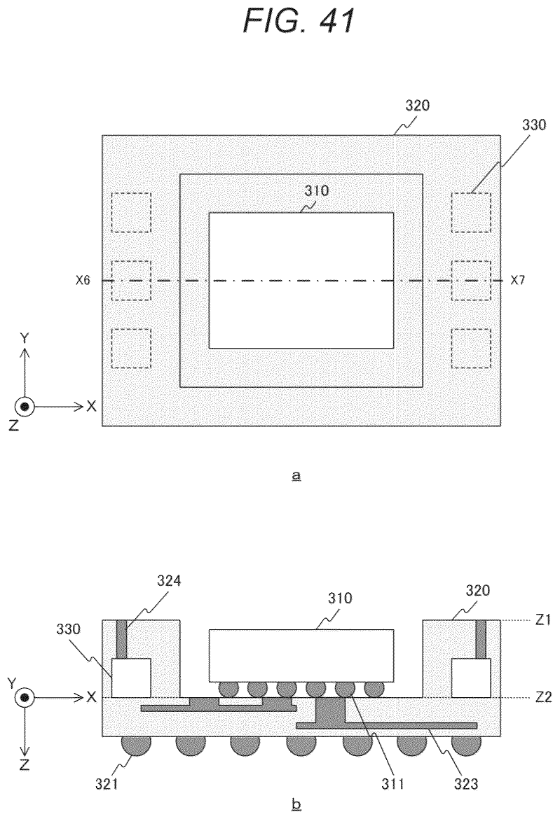

Then, as illustrated in FIG. 41, the passive components 330 are sealed by the substrate material. In the drawing, a illustrates a plan view of a substrate 320, and b illustrates a cross-sectional view of the substrate 320 taken along the line segment X6-X7 in the drawing.

A portion from Z1 to Z2 in b of the drawing is a portion sealed by the substrate material, and this portion is referred to as a dam. In addition, pillars 324 formed with copper (Cu), or the like, are formed on the passive components 330.

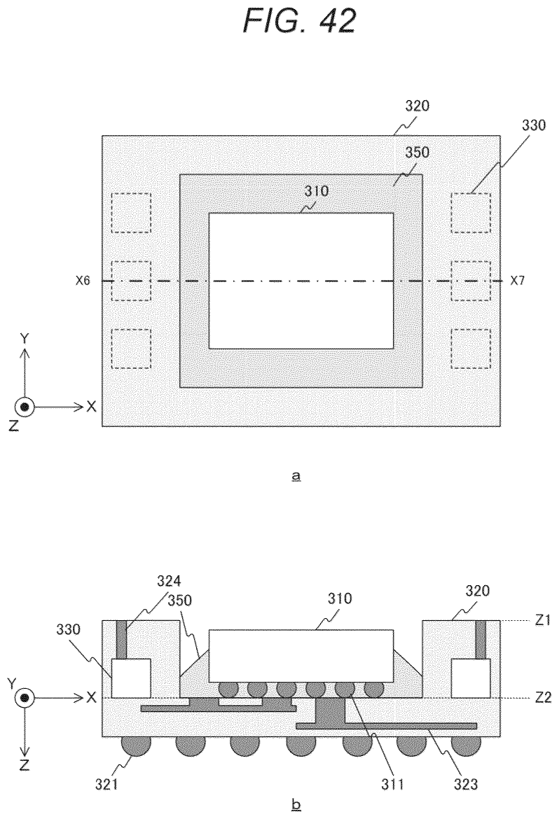

Next, as illustrated in FIG. 42, a portion between an inner wall of the dam and the semiconductor chip 310 is filled with the underfill 350. In the drawing, a illustrates a plan view of a substrate 320, and b illustrates a cross-sectional view of the substrate 320 taken along the line segment X6-X7 in the drawing.

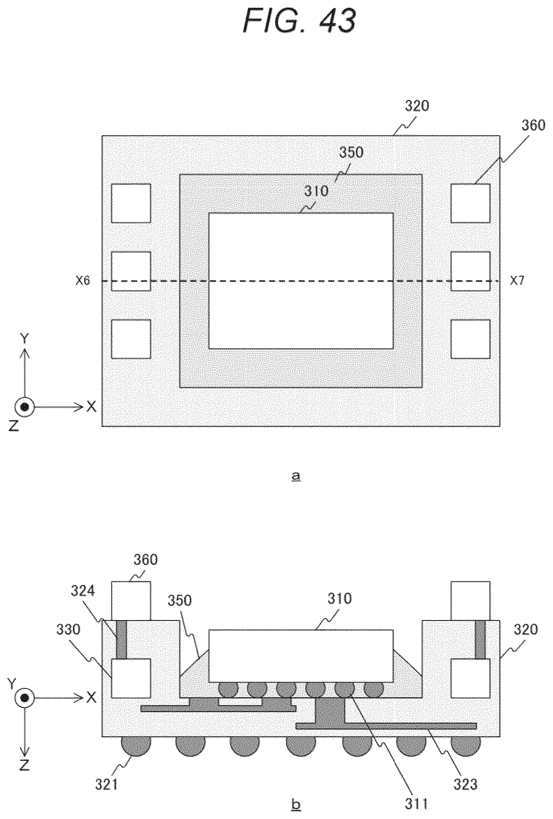

Then, as illustrated in FIG. 43, surface mount technology (SMT) components 360 are disposed on the passive components 330. The surface mount technology components 360 are connected to the passive components 330 via the pillars 324. In the drawing, a illustrates a plan view of a substrate 320, and b illustrates a cross-sectional view of the substrate 320 taken along the line segment X6-X7 in the drawing. Thus, a semiconductor package is manufactured.

A component that cannot be incorporated is preferentially surface-mounted as the surface mount technology component 360 on the upper surface of the dam. On the other hand, by incorporating the passive components 330 and the printed component 323, an upper surface of the dam can be effectively used. Further, the surface mount technology components 360 can be reduced as a result of the passive components 330 and the printed component 323 being incorporated, and for example, a mounting area can be reduced by about 20%.

Further, by incorporating a noise source as the passive components 330 or the printed component 323, it is easy to design for suppressing noise. For example, when electromagnetic interference (EMI) occurs, a decoupling capacitor can be arranged as the printed component 323 in the substrate 320 immediately below the semiconductor chip 310. As a result, a feedback current loop length can be shortened, and the EMI can be suppressed. In this case, inductance of the substrate 320 is reduced to about 1/10 as compared with surface mounting.

As described above, according to the second modification of the fifth embodiment of the present technology, the surface mount technology component 360 is surface-mounted on the upper surface of the dam and the passive components 330 and the printed component 323 are incorporated, so that the upper surface of the dam can be effectively used.

### 6. Example of Application to Mobile Body

The technology according to the present disclosure (present technology) can be applied to various products. For example, the technology according to the present disclosure may be implemented in the form of a device to be mounted on a mobile body of any kind, such as an automobile, an electric vehicle, a hybrid electric vehicle, a motorcycle, a bicycle, a personal mobility, an airplane, a drone, a vessel, or a robot.

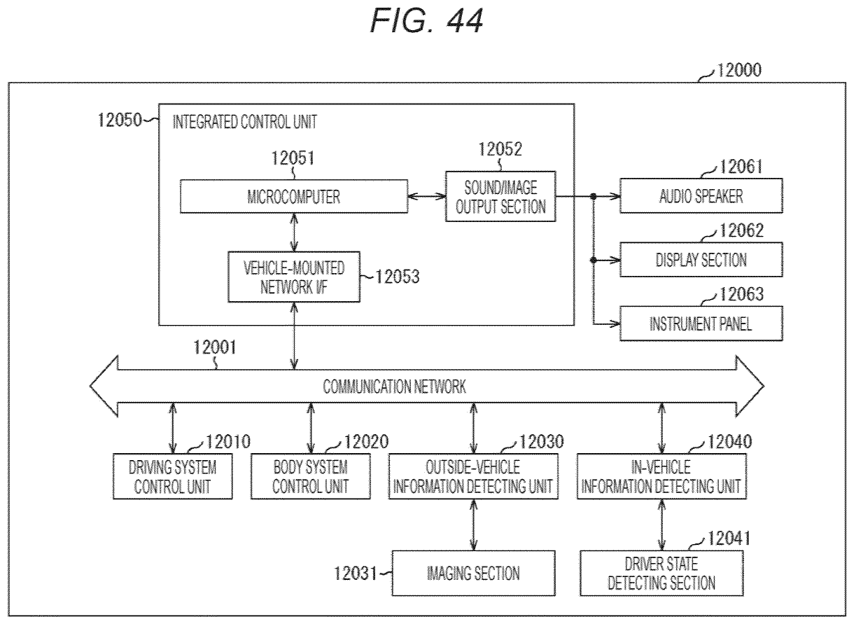

FIG. 44 is a block diagram illustrating an example of schematic configuration of a vehicle control system as an example of a mobile body control system to which the technology according to the present disclosure can be applied.

The vehicle control system 12000 includes a plurality of electronic control units connected to each other via a communication network 12001. In the example illustrated in FIG. 44, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are depicted as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020, on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 44, an audio speaker 12061, a display section 12062, and an instrument panel 12063 are illustrated as examples of the output device. The display section 12062 may, for example, include at least one of an on-board display and a head-up display.

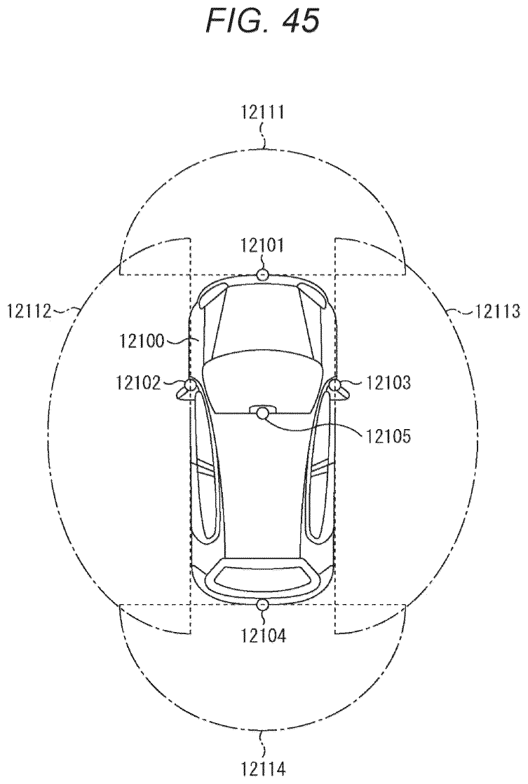

FIG. 45 is a view illustrating an example of an installation position of the imaging section 12031.

In FIG. 45, the imaging section 12031 includes imaging sections 12101, 12102, 12103, 12104, and 12105.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 45 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure is applicable to the imaging section 12031, for example, among the configurations described above. Specifically, the semiconductor package manufactured using the manufacturing process in FIG. 6 can be applied to the imaging section 12031. Applying the technology according to the present disclosure to the imaging section 12031 can suppress warpage upon manufacturing and improve reliability of the system.

Note that the embodiments described above indicate examples for embodying the present technology, and the respective matters in the embodiments and the respective matters specifying the invention in the claims have correspondence relationships. Similarly, the matters specifying the invention in the claims and the matters with the same names in the embodiments of the present technology have correspondence relationships, respectively. However, the present technology is not limited to the embodiments, and can be embodied by applying various modifications to the embodiments without departing from the scope of the present technology.

Note that the effects described in the present specification are merely examples and are not limited, and other effects may also be achieved.

Note that the present technology may also have the following configurations.
(1) A semiconductor package manufacturing method including:
a filling procedure of filling a portion along an outer periphery of each of a plurality of integrated circuits bonded to a wafer with a photosensitive resin as a first underfill;
an exposure procedure of curing the first underfill by exposure;
a sealing procedure of sealing the plurality of integrated circuits and the first underfill by a sealing material; and
a dicing procedure of dividing the wafer into a predetermined number of semiconductor chips.
(2) The semiconductor package manufacturing method according to (1), further including a patterning procedure of forming a grid-like dam on the wafer before the filling procedure.
(3) The semiconductor package manufacturing method according to (2), in which
in the patterning procedure, laser processing and surface modification are performed.
(4) The semiconductor package manufacturing method according to (2), in which
the patterning procedure includes:
a procedure of forming a resist with a predetermined gap left between the plurality of integrated circuits; and
a procedure of forming the dam by plasma processing.
(5) The semiconductor package manufacturing method according to (2), in which
the patterning procedure includes:
a procedure of forming a resist on an entire surface of the wafer; and
a procedure of removing the resist while leaving a grid-like portion by lithography.
(6) The semiconductor package manufacturing method according to any one of (1) to (5), in which
a ratio of a thickness of the sealing material to a thickness of the integrated circuits is not less than 0.5.
(7) The semiconductor package manufacturing method according to (1), in which
in the filling procedure, filling with the first underfill is performed so that the first underfill has a fillet shape when viewed from a direction parallel to a substrate plane of the wafer.
(8) The semiconductor package manufacturing method according to (7), in which
the plurality of integrated circuits includes outer integrated circuits adjacent to an outer periphery of the wafer and inner integrated circuits that do not correspond to the outer integrated circuits, and
in the filling procedure, a portion along an inner side of the outer integrated circuits and outer peripheries of the inner integrated circuits is filled with the first underfill.
(9) The semiconductor package manufacturing method according to (7), in which
in the filling procedure, a portion along part of the outer periphery of each of the plurality of integrated circuits is filled with the first underfill.
(10) The semiconductor package manufacturing method according to any one of (7) to (9), in which
a contact angle of a portion where the first underfill is in contact with the wafer is any of 30°, 45°, and 60°.
(11) The semiconductor package manufacturing method according to (7), in which part of the first underfill is in contact with side walls of the integrated circuits.
(12) The semiconductor package manufacturing method according to (1), further including a patterning procedure of forming a grid-like dam on the wafer before the filling procedure, in which
each of the integrated circuits has a rectangular shape when viewed from a direction perpendicular to the substrate,
a region surrounded by the dam when viewed from the direction perpendicular to the substrate has a rectangular shape, and
a distance from one side of four sides of each of the integrated circuits to an inner wall of the dam when viewed from the direction perpendicular to the substrate is longer than a distance from the remaining three sides to the inner wall of the dam.
(13) The semiconductor package manufacturing method according to (1), further including a patterning procedure of forming a grid-like dam on the wafer before the filling procedure, in which
a U-shaped recess protruding outward is formed in a region surrounded by the dam when viewed from a direction perpendicular to the substrate.
(14) The semiconductor package manufacturing method according to (1), further including a patterning procedure of forming a grid-like dam on the wafer before the filling procedure, in which
part of the dam has a step.
(15) The semiconductor package manufacturing method according to (1), further including a patterning procedure of forming a grid-like dam on the wafer before the filling procedure, in which
part of the dam has a slope.
(16) The semiconductor package manufacturing method according to (1), further including a patterning procedure of forming a grid-like dam on the wafer before the filling procedure, in which
a predetermined number of slits are formed in part of the dam.
(17) The semiconductor package manufacturing method according to (1), in which
a predetermined number of trenches are formed in the wafer.
(18) The semiconductor package manufacturing method according to any one of (1) to (17), further including:
a procedure of mounting the semiconductor chip on a substrate;
a procedure of arranging a passive component around the semiconductor chip;
a procedure of sealing the passive component by a mold resin; and
a procedure of performing filling with a second underfill.
(19) The semiconductor package manufacturing method according to any one of (1) to (17), further including:
a procedure of mounting the semiconductor chip in a cavity provided in a substrate;
a procedure of filling the cavity with a second underfill; and
a procedure of arranging a passive component around the cavity.
(20) The semiconductor package manufacturing method according to any one of (1) to (17), further including:
a procedure of mounting the semiconductor chip on a substrate;
a procedure of arranging a passive component around the semiconductor chip;
a procedure of sealing the passive component by a substrate material;
a procedure of performing filling with a second underfill; and
a procedure of arranging a surface mount technology component on the substrate material.

### REFERENCE SIGNS LIST

110, 111 Integrated circuit
120 Underfill
130 Wafer
130-1 Trench
131, 210, 221 Dam
140 Electrode
150 Sealing material
200, 220 Resist
310 Semiconductor chip
311, 321 Solder ball
320 Substrate
322 Cavity
323 Printed component
324 Pillar
330 Passive component
340 Mold resin
350 Underfill
360 Surface mount technology component
12031 Imaging section

What is claimed is:

1. A semiconductor package manufacturing method, comprising:
a filling procedure of filling a portion along an outer periphery of each of a plurality of integrated circuits bonded to a wafer with a photosensitive resin as a first underfill;
an exposure procedure of curing the first underfill by exposure;
a sealing procedure of sealing the plurality of integrated circuits and the first underfill by a sealing material; and
a dicing procedure of dividing the wafer into a predetermined number of semiconductor chips.

2. The semiconductor package manufacturing method according to claim 1, further comprising a patterning procedure of forming a grid-like dam on the wafer before the filling procedure.

3. The semiconductor package manufacturing method according to claim 2, wherein
laser processing and surface modification are performed in the patterning procedure.

4. The semiconductor package manufacturing method according to claim 2, wherein
the patterning procedure includes:
a procedure of forming a resist with a predetermined gap left between the plurality of integrated circuits; and
a procedure of forming the dam by plasma processing.

5. The semiconductor package manufacturing method according to claim 2, wherein
the patterning procedure includes:
a procedure of forming a resist on an entire surface of the wafer; and
a procedure of removing the resist while leaving a grid-like portion by lithography.

6. The semiconductor package manufacturing method according to claim 1, wherein
a ratio of a thickness of the sealing material to a thickness of the integrated circuits is not less than 0.5.

7. The semiconductor package manufacturing method according to claim 1, wherein
in the filling procedure, filling with the first underfill is performed so that the first underfill has a fillet shape when viewed from a direction parallel to a substrate plane of the wafer.

8. The semiconductor package manufacturing method according to claim 7, wherein
the plurality of integrated circuits includes outer integrated circuits adjacent to an outer periphery of the wafer and inner integrated circuits that do not correspond to the outer integrated circuits, and
in the filling procedure, a portion along an inner side of the outer integrated circuits and outer peripheries of the inner integrated circuits is filled with the first underfill.

9. The semiconductor package manufacturing method according to claim 7, wherein
in the filling procedure, a portion along part of the outer periphery of each of the plurality of integrated circuits is filled with the first underfill.

10. The semiconductor package manufacturing method according to claim 7, wherein
a contact angle of a portion where the first underfill is in contact with the wafer is any one of 30°, 45°, and 60°.

11. The semiconductor package manufacturing method according to claim 7, wherein
part of the first underfill is in contact with side walls of the integrated circuits.

12. The semiconductor package manufacturing method according to claim 1, further comprising a patterning procedure of forming a grid-like dam on the wafer before the filling procedure, wherein
each of the integrated circuits has a rectangular shape when viewed from a direction perpendicular to the substrate,
a region surrounded by the dam when viewed from the direction perpendicular to the substrate has a rectangular shape, and
a distance from one side of four sides of each of the integrated circuits to an inner wall of the dam when viewed from the direction perpendicular to the substrate is longer than a distance from the remaining three sides to the inner wall of the dam.

13. The semiconductor package manufacturing method according to claim 1, further comprising a patterning procedure of forming a grid-like dam on the wafer before the filling procedure, wherein
a U-shaped recess protruding outward is formed in a region surrounded by the dam when viewed from a direction perpendicular to the substrate.

14. The semiconductor package manufacturing method according to claim 1, further comprising a patterning procedure of forming a grid-like dam on the wafer before the filling procedure, wherein
part of the dam has a step.

15. The semiconductor package manufacturing method according to claim 1, further comprising a patterning procedure of forming a grid-like dam on the wafer before the filling procedure, wherein
part of the dam has a slope.

16. The semiconductor package manufacturing method according to claim 1, further comprising a patterning procedure of forming a grid-like dam on the wafer before the filling procedure, wherein
a predetermined number of slits are formed in part of the dam.

17. The semiconductor package manufacturing method according to claim 1, wherein
a predetermined number of trenches are formed in the wafer.

18. The semiconductor package manufacturing method according to claim 1, further comprising:
a procedure of mounting the semiconductor chip on a substrate;
a procedure of arranging a passive component around the semiconductor chip;
a procedure of sealing the passive component by a mold resin; and
a procedure of performing filling with a second underfill.

19. The semiconductor package manufacturing method according to claim 1, further comprising:
a procedure of mounting the semiconductor chip in a cavity provided in a substrate;
a procedure of filling the cavity with a second underfill; and
a procedure of arranging a passive component around the cavity.

20. The semiconductor package manufacturing method according to claim 1, further comprising:
a procedure of mounting the semiconductor chip on a substrate;
a procedure of arranging a passive component around the semiconductor chip;
a procedure of sealing the passive component by a substrate material;
a procedure of performing filling with a second underfill; and
a procedure of arranging a surface mount technology component on the substrate material.
